(19) United States
(12) Patent Application Publication
(10) Pub. No.: US 2011/0292007 A1
(43) Pub. Date: Dec. 1, 2011

(54) SHIFT REGISTER, DISPLAY DEVICE PROVIDED WITH SAME, AND METHOD OF DRIVING SHIFT REGISTER

(75) Inventor: Seiji Ohhashi, Osaka-shi (JP)

(73) Assignee: SHARP KABUSHIKI KAISHA, Osaka-shi, Osaka (JP)

(21) Appl. No.: 13/138,414

(22) PCT Filed: Feb. 3, 2010
(86) PCT No.: PCT/JP2010/051471

§ 371 Date: Aug. 11, 2011

(30) Foreign Application Priority Data
Apr. 8, 2009 (JP) 2009-093519

(51) Int. Cl. G09G 5/00; G11C 19/00

(52) U.S. Cl. 345/204; 377/77

(57) ABSTRACT

A display device is implemented that does not cause abnormal operation even if a shift in threshold voltage occurs in a transistor composing a shift register. Each bistable circuit includes an output terminal that outputs a state signal; a thin film transistor having a drain terminal to which a clock signal is provided, and having a source terminal connected to the output terminal; a thin film transistor for charging a region netA connected to a gate terminal of the thin film transistor; a thin film transistor having a drain terminal connected to the netA; a thin film transistor having a drain terminal connected to the output terminal; and a second node potential control portion that detects a higher one of the threshold voltages of the thin film transistors and sets, based on the detected threshold voltage, the potential of a region netB connected to gate terminals of the thin film transistors to a relatively low-level potential and a relatively high-level potential.

### TECHNICAL FIELD

The present invention relates to a shift register provided in a drive circuit of an active matrix-type display device and a method of driving the shift register.

### BACKGROUND ART

Conventionally, there is known an active matrix-type display device in which a plurality of gate bus lines (scanning signal lines) and a plurality of source bus lines (video signal lines) are arranged in a grid pattern and a plurality of pixel formation portions are arranged in a matrix form at the respective intersections of the plurality of gate bus lines and the plurality of source bus lines. Each pixel formation portion includes a TFT (Thin Film Transistor) which is a switching element having a gate terminal connected to a gate bus line passing through a corresponding intersection, and having a source terminal connected to a source bus line passing through the intersection; a pixel capacitance for holding a pixel value; and the like. The active matrix-type display device is also provided with a gate driver (scanning signal line drive circuit) that drives the plurality of gate bus lines, and a source driver (video signal line drive circuit) that drives the plurality of source bus lines.

A video signal indicating a pixel value is transmitted through a source bus line, but each source bus line cannot transmit video signals indicating pixel values for a plurality of rows at a time (at the same time). Therefore, writing of video signals to the pixel capacitances in the above-described pixel formation portions arranged in a matrix form is sequentially performed row by row. Hence, in order that the plurality of gate bus lines are sequentially selected for a predetermined period of time, the gate driver is composed of a shift register including a plurality of stages.

FIG. 19 is a block diagram showing an exemplary configuration of a shift register 910 included in a conventional gate driver. As shown in FIG. 19, the gate driver is composed of an n-stage shift register 910. Each stage of the shift register 910 is a bistable circuit which is in either one of two states (a first state and a second state) at each time point and which outputs a signal (state signal) indicating the state, as a scanning signal GOUT. As such, the shift register 910 is composed of n bistable circuits SR(1) to SR(n). To the shift register 910 are provided three-phase clock signals GCK1, GCK2, and GCK3 and a gate start pulse signal GSP which is a signal for starting scanning of the gate bus lines. Each bistable circuit is provided with an input terminal for receiving any one of the three-phase clock signals as a first clock CKA; an input terminal for receiving any one of the three-phase clock signals as a second clock CKB; an input terminal for receiving the gate start pulse signal GSP or a state signal OUT outputted from its previous stage, as a set signal SET; and an output terminal for outputting a state signal OUT.

FIG. 20 is a circuit diagram showing an exemplary configuration of one stage (one bistable circuit) of the above-described conventional shift register 910. The bistable circuit includes six thin film transistors T91 to T96 and a capacitor C91. In addition, the bistable circuit has input terminals for a power supply line VDD which supplies a relatively high-level potential VGH and input terminals for a power supply line VSS which supplies a relatively low-level potential VGL, and three input terminals 91 to 93 and one output terminal 99. Note that the input terminal that receives a first clock CKA is denoted by reference numeral 91, the input terminal that receives a set signal SET is denoted by reference numeral 92, and the input terminal that receives a second clock CKB is denoted by reference numeral 93. Note also that the potential VGH corresponds to a potential that places a thin film transistor in a pixel formation portion in an on state, and the potential VGL corresponds to a potential that places the thin film transistor in an off state.

A gate terminal of the thin film transistor T91, a source terminal of the thin film transistor T92, and a drain terminal of the thin film transistor T93 are connected to one another. Note that a region (wiring line) where they are connected to one another is referred to as a “netA” for convenience's sake. Also, a gate terminal of the thin film transistor T93, a gate terminal of the thin film transistor T94, a source terminal of the thin film transistor T95, and a drain terminal of the thin film transistor T96 are connected to one another. Note that a region (wiring line) where they are connected to one another is referred to as a “netB” for convenience's sake.

For the thin film transistor T91, the gate terminal is connected to the netA, the drain terminal is connected to the input terminal 91, and the source terminal is connected to the output terminal 99. For the thin film transistor T92, the gate terminal is connected to the input terminal 92, the drain terminal is connected to the power supply line VDD, and the source terminal is connected to the netA. For the thin film transistor T93, the gate terminal is connected to the netB, the drain terminal is connected to the netA, and the source terminal is connected to the power supply line VSS. For the thin film transistor T94, the gate terminal is connected to the netB, the drain terminal is connected to the output terminal 99, and the source terminal is connected to the power supply line VSS. For the thin film transistor T95, the gate terminal is connected to the input terminal 93, the drain terminal is connected to the power supply line VDD, and the source terminal is connected to the netB. For the thin film transistor T96, the gate terminal is connected to the input terminal 92, the drain terminal is connected to the netB, and the source terminal is connected to the power supply line VSS. For the capacitor C91, one end is connected to the netA and the other end is connected to the output terminal 99.

In a configuration such as that described above, three-phase clock signals GCK1, GCK2, and GCK3 having waveforms shown in FIGS. 21A to 21C and a gate start pulse signal GSP having a waveform shown in FIG. 21D are provided to the shift register 910. Then, scanning signals GOUT(1) to GOUT(n) which sequentially go to a high level for one horizontal scanning period, as shown in FIGS. 21E to 21G, are outputted from the shift register 910.

With reference to FIGS. 20 and 22A to 22F, the operation of each stage (bistable circuit) of the shift register 910 will be described below. Note that FIGS. 22A to 22F show waveforms for the bistable circuit SR(1) of the first stage, and for the bistable circuits SR(2) to SR(n) of the second and subsequent stages, the same waveforms as those shown in FIGS. 22A to 22F appear with a delay of one horizontal scanning period. Namely, the n bistable circuits SR(1) to SR(n) perform the same operation with the exception of timing. Accordingly, in the following, description will be made focusing only on the bistable circuit SR(1) of the first stage.

During the operation of the display device, a first clock CKA having a waveform shown in FIG. 22A is provided to the input terminal 91, and a second clock CKB having a waveform shown in FIG. 22B is provided to the input terminal 93. During a period before time point to, the potentials of a set signal SET, a netA, and a state signal OUT are VGL and the potential of a netB is VGH.

When reaching time point t0, a pulse of the set signal SET is provided to the input terminal 92. By this, the thin film transistors T92 and T96 are placed in an on state. In addition, at time point t0, the potential of the second clock CKB provided to the input terminal 93 changes from VGL to VGH. By this, the thin film transistor T95 is placed in an on state. By the thin film transistor T92 being placed in an on state, the potential of the netA is brought to VGH and thus the thin film transistor T91 is placed in an on state. In addition, the thin film transistor T95 is placed in an on state and the thin film transistor T96 is also placed in an on state, whereby a current flows from the drain terminal of the thin film transistor T95 to the source terminal of the thin film transistor T96. Hence, the potential of the netB is brought to VGL. By this, the thin film transistors T93 and T94 are placed in an off state. By the thin film transistor T93 being placed in an off state, during the period from t0 to t1, the potential of the netA does not decrease.

The thin film transistor T91 is, as described above, placed in an on state at time point t0. However, during the period from t0 to t1, the potential of the first clock CKA provided to the input terminal 91 is VGL. Hence, the potential of the state signal OUT outputted from the output terminal 99 is maintained at VGL. At this time, a voltage with the magnitude “VGH-VGL” is applied between the gate and source of the thin film transistor T91 (between both end terminals of the capacitor C91).

When reaching time point t1, the potentials of the set signal SET and the second clock CKB change from VGH to VGL. By this, the thin film transistors T92, T95, and T96 are placed in an off state. In addition, at time point t1, the potential of the first clock CKA changes from VGL to VGH. At this time, since the voltage between the gate and source of the thin film transistor T91 is maintained at “VGH-VGL” by the capacitor C91, the thin film transistor T91 is in an on state. In addition, a parasitic capacitance (not shown) is formed between the gate and drain of the thin film transistor T91. Due to the above, the drain potential of the thin film transistor T91 increases with an increase in the potential of the input terminal 91, and thus, the potential of the netA further increases from VGH through the parasitic capacitance. As a result, a high voltage is applied to the gate terminal of the thin film transistor T91 and thus the potential of the state signal OUT increases to the potential VGH of the first clock CKA. By this, a gate bus line connected to the output terminal 99 of this bistable circuit is placed in a selected state. Meanwhile, during the period from t1 to t2, the thin film transistor T95 is in an off state, and thus, the potential of the netB is maintained at VGL. Hence, during this period, the thin film transistor T93 is maintained in an off state and thus the potential of the netA is also maintained. Note that for the increase in the potential of the netA at time point t1, the potential ideally increases to a level twice the VGH, but in practice the potential does not increase to the level twice the VGH due to the presence of the parasitic capacitances, resistances, etc., of the netA, the input terminal 91, the output terminal 99, and the thin film transistor T91.

When reaching time point t2, the potential of the first clock CKA changes from VGH to VGL. At time point t2, since the potential of the netA is higher than VGH, when the drain potential of the thin film transistor T91 decreases with a decrease in the potential of the input terminal 91, a current flows from the source terminal to the drain terminal of the thin film transistor T91. By this, the potential of the output terminal 99, i.e., the potential of the state signal OUT, decreases to VGL. Accordingly, the gate bus line connected to the output terminal 99 of this bistable circuit is placed in a non-selected state. Note that during the period from t2 to t3, since the potential of the second clock CKB is VGL and the thin film transistor T95 is in an off state, the potential of the netB is maintained at VGL. Hence, during this period, the thin film transistor T93 is maintained in an off state and the potential of the netA is also maintained.

When reaching time point t3, the potential of the second clock CKB changes from VGL to VGH. Hence, the thin film transistor T95 is placed in an on state. By this, the potential of the netB is brought to VGH and thus the thin film transistors T93 and T94 are placed in an on state. By the thin film transistor T93 being placed in an on state, the potential of the netA is brought to VGL and thus the thin film transistor T91 is placed in an off state. In addition, by the thin film transistor T94 being placed in an on state, the potential of the state signal OUT is maintained at VGL.

The operation such as that described above is sequentially performed by the n bistable circuits SR(1) to SR(n) such that the timing is delayed by one horizontal scanning period. By this, in each frame period, n gate bus lines GL1 to GLn are sequentially placed in a selected state for one horizontal scanning period.

### PRIOR ART DOCUMENT

### Patent Document

[Patent Document 1] Japanese Unexamined Patent Application Publication (Translation of PCT Application) No. 6-505605

### SUMMARY OF THE INVENTION

### Problems to be Solved by the Invention

However, according to the above-described conventional configuration, the display device may cause abnormal operation due to a shift in the threshold voltage of a TFT (Thin Film Transistor). This will be described below.

A configuration using amorphous silicon for semiconductor layers of TFTs in a display device is conventionally known. In particular, many middle- and large-sized liquid crystal display devices employ the configuration using amorphous silicon. The configuration using amorphous silicon has an advantage that the fabrication cost is lower than that for a configuration using low-temperature polysilicon. However, it is known that in a TFT using amorphous silicon for a semiconductor layer, when a voltage with a positive magnitude is applied between the gate and the drain or between the gate and the source, the threshold voltage of the TFT shifts from an initial state. For example, in the case of an n-type TFT, comparing a threshold voltage Vth0 in an initial state with a threshold voltage Vth1 after a shift, Vth1 is higher than Vth0.

Meanwhile, in a linear region of the current-voltage characteristics of a TFT, the magnitude of a drain-source current Ids is represented by the following equation (1):

Ids=(W/L)×μ×Cox×(Vgs−Vth−(Vds/2))×Vds (1)

where W is the channel width of the TFT, L is the channel length of the TFT, μ is the carrier mobility, Cox is the gate oxide film capacitance, Vgs is the gate-source voltage, Vth is the threshold voltage, and Vds is the drain-source voltage.

In the above equation (1), when the value of the threshold voltage Vth increases, the value of (Vgs−Vth−(Vds/2)) decreases, and thus, the magnitude of the drain-source current Ids decreases. Namely, by the threshold voltage shifting, the drive capability of the TFT decreases.

Here, as is understood from FIG. 22E, the potential of the netB in the bistable circuit SR(1) of the first stage in the shift register 910 is VGH during all periods in one frame period, except the period from t0 to t3. In the case of a common display device with a frame frequency of 60 Hz, since one frame period is 1/60 seconds, each gate bus line is placed in a selected state every 1/60 seconds. The selected period (period length) of each gate bus line is substantially equal to a period (period length) obtained by dividing one frame period (period length) by the number of gate bus lines. For example, in the case of a WXGA-type display device, since the number of gate bus lines is 768, the selected period of each gate bus line is about 21.7 microseconds. Accordingly, the period from t0 to t3 is about 65.1 microseconds. Since this period is sufficiently a short period compared to one frame period, it can be said that the potential of the netB is VGH during most periods in one frame period. In the configuration shown in FIG. 20, the source potentials of the thin film transistors T93 and T94 are VGL. Hence, during most periods in one frame period, a voltage with a positive magnitude is applied between the gate and source of each of the thin film transistors T93 and T94. Therefore, the threshold voltages of the thin film transistors T93 and T94 increase according to the operating time of the display device. By this, the drive capability of the thin film transistors T93 and T94 gradually decreases. As a result, for example, at time point t3 (see FIG. 22D), the potential of the netA does not decrease to VGL. In this case, when the potential of the first clock CKA increases from VGL to VGH at time point t4, the drain potential of the thin film transistor T91 increases and thus the potential of the netA increases due to a parasitic capacitance between the gate and drain of the thin film transistor T91. If, due to the increase in the potential of the netA, the voltage between the gate and source of the thin film transistor T91 becomes higher than the threshold voltage, then the thin film transistor T91 is placed in an on state and thus the potential of the state signal OUT is brought to a level higher than VGL. In this manner, despite the fact that a gate bus line connected to an output terminal 99 of a given bistable circuit is not in a selected period, a voltage higher than VGL is applied to the gate bus line. As a result, the operation of the display device becomes abnormal.

An object of the present invention is therefore to implement a display device that does not cause abnormal operation even if a shift in threshold voltage occurs in a transistor composing a shift register.

### Means for Solving the Problems

A first aspect of the present invention is directed to a shift register comprising a plurality of bistable circuits having a first state and a second state and connected to each other in series, the plurality of bistable circuits being sequentially placed in the first state based on a clock signal, the clock signal being provided from an external source of each bistable circuit and periodically repeating a high-level potential and a low-level potential, wherein

each bistable circuit includes:
an output node that outputs a state signal indicating either one of the first state and the second state;
a first transistor having a second electrode to which the clock signal is provided, and having a third electrode connected to the output node;
a first node charging portion for charging a first node based on the state signal outputted from a bistable circuit of a previous stage of the bistable circuit, the first node being connected to a first electrode of the first transistor;
a third transistor having a second electrode connected to the first node and having a third electrode to which a low-level potential is provided;
a fourth transistor having a second electrode connected to the output node and having a third electrode to which a low-level potential is provided; and
a second node potential control portion for setting a potential of a second node to a relatively low-level potential and a relatively high-level potential, the second node being connected to a first electrode of the third transistor and a first electrode of the fourth transistor, and

the second node potential control portion includes:
a fifth transistor having a first electrode to which a previous stage state signal that is the state signal outputted from a bistable circuit of a previous stage of each bistable circuit is provided, or a signal that goes to a high level at least during a period during which the previous stage state signal is placed in the first state is provided, and having a second electrode connected to the second node; and
a sixth transistor having a first electrode connected to the second node, having a second electrode to which a third electrode of the fifth transistor is connected, and having a third electrode to which a potential with a magnitude is provided, the magnitude being equal to the low-level potentials provided to the third electrode of the third transistor and the third electrode of the fourth transistor.

According to a second aspect of the present invention, in the first aspect of the present invention,

the third transistor, the fourth transistor, and the sixth transistor have an equal ratio of a channel width to a channel length.

According to a third aspect of the present invention, in the second aspect of the present invention,

the sixth transistor is disposed to be adjacent to at least one of the third transistor and the fourth transistor.

According to a fourth aspect of the present invention, in the first aspect of the present invention,

the second node potential control portion includes:
a second node potential low-level setting portion including the fifth transistor and the sixth transistor and setting the potential of the second node to the relatively low-level potential during a period during which the third transistor and the fourth transistor are to be placed in an off state; and
a second node potential high-level setting portion that sets the potential of the second node to the relatively high-level potential by increasing the potential of the second node by a predetermined amount of voltage upon changing from a period during which the third transistor and the fourth transistor are to be placed in an off state to a period during which the third transistor and the fourth transistor are to be placed in an on state.

According to a fifth aspect of the present invention, in the fourth aspect of the present invention,

the second node potential high-level setting portion includes:
a seventh transistor having a first electrode to which a previous stage state signal that is the state signal outputted from a bistable circuit of a previous stage of each bistable circuit is provided, or a signal that goes to a high level at least during a period during which the previous stage state signal is placed in the first state is provided, and having a third electrode to which a low-level potential is provided;
a third node charging portion for charging a third node connected to a second electrode of the seventh transistor, based on a subsequent stage state signal that is the state signal outputted from a bistable circuit of a subsequent stage of each bistable circuit, or based on a signal that goes to a high level at least during a period during which the subsequent stage state signal is placed in the first state; and
a capacitor having one end connected to the second node and having an other end connected to the third node.

According to a sixth aspect of the present invention, in the fifth aspect of the present invention,

the third node charging portion comprises an eighth transistor having a first electrode to which a signal that goes to a high level at least during a period during which the subsequent stage state signal is placed in the first state is provided, having a second electrode to which a high-level potential is provided, and having a third electrode connected to the third node.

According to a seventh aspect of the present invention, in the fifth aspect of the present invention,

the second node potential high-level setting portion further includes a ninth transistor having a first electrode which is connected to the output node or to which a signal that goes to a high level at least during a period during which the state signal outputted from each bistable circuit is placed in the first state is provided, having a second electrode connected to the third node, and having a third electrode to which a low-level potential is provided.

According to an eighth aspect of the present invention, in the fourth aspect of the present invention,

the second node potential high-level setting portion includes:
a seventh transistor having a first electrode to which a clock signal that goes to a high level at least during the period during which the previous stage state signal is placed in the first state is provided, and having a third electrode to which a low-level potential is provided;
an eighth transistor having a first electrode to which a clock signal that goes to a high level at least during a period during which a subsequent stage state signal is placed in the first state is provided, having a second electrode to which a high-level potential is provided, and having a third electrode connected to a third node connected to a second electrode of the seventh transistor, the subsequent stage state signal being the state signal outputted from a bis table circuit of a subsequent stage of each bistable circuit;
a ninth transistor having a first electrode to which a clock signal that goes to a high level at least during a period during which the state signal outputted from each bistable circuit is placed in the first state is provided, having a second electrode connected to the third node, and having a third electrode to which a low-level potential is provided; and
a capacitor having one end connected to the second node and having an other end connected to the third node,

three-phase clock signals with different phases are provided to the first electrode of the seventh transistor, the first electrode of the eighth transistor, and the first electrode of the ninth transistor, respectively, and

a same clock signal is provided to the first electrode of the seventh transistor and the first electrode of the fifth transistor.

According to a ninth aspect of the present invention, in the first aspect of the present invention,

each bistable circuit further includes a second node initialization portion that sets the potential of the second node to a predetermined potential based on an initialization pulse provided to the plurality of bistable circuits at common timing.

According to a tenth aspect of the present invention, in the ninth aspect of the present invention,

the second node initialization portion includes a tenth transistor having a first electrode to which the initialization pulse is provided, having a second electrode to which a high-level potential is provided, and having a third electrode connected to the second node.

According to an eleventh aspect of the present invention, in the first aspect of the present invention,

each transistor is formed using amorphous silicon or microcrystalline silicon for a semiconductor layer.

A twelfth aspect of the present invention is directed to a scanning signal line drive circuit of a display device that drives a plurality of scanning signal lines arranged in a display unit, the scanning signal line drive circuit comprises a shift register according to any one of the first through the eleventh aspects of the present invention, wherein

the plurality of bistable circuits are provided so as to have a one-to-one correspondence with the plurality of scanning signal lines, and each bistable circuit provides the state signal outputted from the output node, to a corresponding scanning signal line of the bistable circuit as a scanning signal.

A thirteenth aspect of the present invention is directed to a display device including the display unit and comprising a scanning signal line drive circuit according to the twelfth aspect of the present invention.

A fourteenth aspect of the present invention is directed to a method of driving a shift register including a plurality of bistable circuits having a first state and a second state and connected to each other in series, the plurality of bistable circuits being sequentially placed in the first state based on a clock signal, the clock signal being provided from an external source of each bistable circuit and periodically repeating a high-level potential and a low-level potential, the method comprising:

a first driving step of changing each bistable circuit from the second state to the first state based on a first instruction signal provided from an external source of the bistable circuit; and

a second driving step of changing each bistable circuit from the first state to the second state based on a second instruction signal provided from an external source of the bistable circuit, wherein

each bistable circuit includes:
an output node that outputs a state signal indicating either one of the first state and the second state;
a first transistor having a second electrode to which the clock signal is provided, and having a third electrode connected to the output node;
a first node charging portion for charging a first node based on the state signal outputted from a bistable circuit of a previous stage of the bistable circuit and provided as the first instruction signal, the first node being connected to a first electrode of the first transistor;
a third transistor having a second electrode connected to the first node and having a third electrode to which a low-level potential is provided;
a fourth transistor having a second electrode connected to the output node and having a third electrode to which a low-level potential is provided; and
a second node potential control portion for setting a potential of a second node to a relatively low-level potential and a relatively high-level potential, the second node being connected to a first electrode of the third transistor and a first electrode of the fourth transistor,

the second node potential control portion includes:
a fifth transistor having a first electrode to which a previous stage state signal that is the state signal outputted from the bistable circuit of the previous stage of the bistable circuit is provided, or a signal that goes to a high level at least during a period during which the previous stage state signal is placed in the first state is provided, and having a second electrode connected to the second node; and
a sixth transistor having a first electrode connected to the second node, having a second electrode to which a third electrode of the fifth transistor is connected, and having a third electrode to which a potential with a magnitude is provided, the magnitude being equal to the low-level potentials provided to the third electrode of the third transistor and the third electrode of the fourth transistor,

in the first driving step, the potential of the second node is set to the relatively low-level potential by the second node potential control portion, and

in the second driving step, the potential of the second node is set to the relatively high-level potential by the second node potential control portion.

According to a fifteenth aspect of the present invention, in the fourteenth aspect of the present invention,

the second node potential control portion includes:
a second node potential low-level setting portion including the fifth transistor and the sixth transistor, for setting the potential of the second node to the relatively low-level potential; and
a second node potential high-level setting portion for setting the potential of the second node to the relatively high-level potential,

the first driving step includes:
a first node charging step of charging the first node; and
an output node charging step of changing the state indicated by the state signal from the second state to the first state by changing a potential of the clock signal provided to the second electrode of the first transistor from a low level to a high level when the first node is being charged,

in the first node charging step, the potential of the second node is set to the relatively low-level potential by the second node potential low-level setting portion, and

in the second driving step, the potential of the second node is set to the relatively high-level potential by increasing the potential of the second node by a predetermined amount of voltage by the second node potential high-level setting portion.

According to a sixteenth aspect of the present invention, in the fifteenth aspect of the present invention,

the second node potential high-level setting portion includes:
a seventh transistor having a first electrode to which a clock signal that goes to a high level at least during a period during which the previous stage state signal is placed in the first state is provided, and having a third electrode to which a low-level potential is provided;
an eighth transistor having a first electrode to which a clock signal that goes to a high level at least during a period during which a subsequent stage state signal is placed in the first state is provided, having a second electrode to which a high-level potential is provided, and having a third electrode connected to a third node connected to a second electrode of the seventh transistor, the subsequent stage state signal being the state signal outputted from a bistable circuit of a subsequent stage of each bistable circuit;
a ninth transistor having a first electrode to which a clock signal that goes to a high level at least during a period during which the state signal outputted from each bistable circuit is placed in the first state is provided, having a second electrode connected to the third node, and having a third electrode to which a low-level potential is provided; and
a capacitor having one end connected to the second node and having an other end connected to the third node,

three-phase clock signals with different phases are provided to the first electrode of the seventh transistor, the first electrode of the eighth transistor, and the first electrode of the ninth transistor, respectively, and

a same clock signal is provided to the first electrode of the seventh transistor and the first electrode of the fifth transistor.

According to a seventeenth aspect of the present invention, in the fourteenth aspect of the present invention,

the method of driving a shift register further comprises a second node initializing step of setting the potentials of the second nodes in the plurality of bistable circuits to a predetermined potential based on an initialization pulse provided to the plurality of bistable circuits at common timing.

### Effect of the Invention

According to the first aspect of the present invention, a second electrode of a third transistor is connected to a first node connected to a first electrode of a first transistor for controlling the state of a state signal outputted from an output node, and a second electrode of a fourth transistor is connected to the output node. In addition, a first electrode of a sixth transistor is connected to a second node connected to a first electrode of the third transistor and a first electrode of the fourth transistor, and a potential with a magnitude equal to a low-level potential provided to a third electrode of the third transistor and a third electrode of the fourth transistor is provided to a third electrode of the sixth transistor. Furthermore, a third electrode of a fifth transistor is connected to a second electrode of the sixth transistor, and a second electrode of the fifth transistor is connected to the second node. In such a configuration, when the fifth transistor is placed in a conducting state, the first and second electrodes of the sixth transistor are placed in a short-circuit state through the second node. By this, the potential of the second node is set according to the threshold voltage of the sixth transistor. Namely, even if the threshold voltage of the sixth transistor gradually increases, the potential of the second node can be increased with the increase in threshold voltage. Here, since the first electrode of the third transistor and the first electrode of the fourth transistor are connected to the second node, by the potential of the second node increasing with the increase in the threshold voltage of the sixth transistor, a reduction in the drive capability of the third transistor and the fourth transistor can be suppressed. By this, the occurrence of abnormal operation of a display device, etc., resulting from a shift in the threshold voltage of a transistor composing a shift register is prevented.

According to the second aspect of the present invention, the threshold voltages of the third transistor, the fourth transistor, and the sixth transistor are equal. Thus, the potential of the second node increases according to an increase in the threshold voltages of the third transistor, the fourth transistor, and the sixth transistor. Hence, a reduction in the drive capability of each transistor is securely suppressed and thus the occurrence of abnormal operation of a display device, etc., resulting from a shift in the threshold voltage of a transistor is securely prevented.

According to the third aspect of the present invention, since the occurrence of variations in characteristics between transistors is suppressed, the occurrence of abnormal operation of a display device, etc., resulting from a shift in the threshold voltage of a transistor is more securely prevented.

According to the fourth aspect of the present invention, the amount of change in the potential of the second node upon changing from a period during which the third transistor and the fourth transistor are to be placed in an off state to a period during which the third transistor and the fourth transistor are to be placed in an on state is constant. Namely, without making the configuration of a second node potential high-level setting portion complicated, a shift register capable of preventing the occurrence of abnormal operation of a display device, etc., resulting from a shift in the threshold voltage of a transistor is implemented.

According to the fifth aspect of the present invention, since a capacitor having one end connected to the second node and having the other end connected to a third node is provided, by increasing the potential of the third node by a certain value upon changing from a period during which the third transistor and the fourth transistor are to be placed in an off state to a period during which the third transistor and the fourth transistor are to be placed in an on state, the potential of the second node can also be increased by a certain value.

According to the sixth aspect of the present invention, in a configuration in which a third node charging portion is implemented by a transistor, the same effect as that obtained in the fifth aspect of the present invention is obtained.

According to the seventh aspect of the present invention, the potential of the third node is securely brought to a low level at the time point immediately before changing from a period during which the third transistor and the fourth transistor are to be placed in an off state to a period during which the third transistor and the fourth transistor are to be placed in an on state. Hence, the potential of the second node can be securely increased by a certain value when changing from a period during which the third transistor and the fourth transistor are to be placed in an off state to a period during which the third transistor and the fourth transistor are to be placed in an on state.

According to the eighth aspect of the present invention, three-phase clock signals are provided to first electrodes of transistors composing the second node potential high-level setting portion. Namely, the on-duty of each of the transistors (the percentage of a period during which the transistor is placed in an on state) becomes substantially one-third, and thus, a shift in threshold voltage in a positive direction for each transistor is suppressed. By this, the occurrence of abnormal operation of a display device, etc., resulting from a shift in the threshold voltage of a transistor is more effectively prevented.

According to the ninth aspect of the present invention, the potentials of the second nodes in all bistable circuits composing the shift register are set to a predetermined potential at the same timing (the timing of an initialization pulse). Here, by employing a configuration in which, for example, an initialization pulse is provided to the shift register every frame period, the potentials of the second nodes are securely brought to the predetermined potential every frame period. In addition, by setting the potentials of the second nodes such that the third transistors and the fourth transistors are placed in an on state every frame period, the potentials of the first nodes and the potentials of the output nodes are also brought to certain potentials every frame period. As such, the states of the second nodes, the first nodes, and the output nodes are initialized every predetermined period, stabilizing the operation of the shift register. By this, the occurrence of abnormal operation of a display device, etc., is effectively prevented.

According to the tenth aspect of the present invention, in a configuration in which a second node initialization portion is implemented by a transistor, the same effect as that obtained in the ninth aspect of the present invention is obtained.

According to the eleventh aspect of the present invention, in a shift register formed of transistors using amorphous silicon or microcrystalline silicon for semiconductor layers, the same effect as that obtained in the first aspect of the present invention is obtained.

According to the twelfth aspect of the present invention, a scanning signal line drive circuit is implemented that includes a shift register with which the same effect as that obtained in any of the first to eleventh aspects of the present invention is obtained.

According to the thirteenth aspect of the present invention, a display device is implemented that includes a scanning signal line drive circuit with which the same effect as that obtained in the twelfth aspect of the present invention is obtained.

### BRIEF DESCRIPTION OF THE DRAWINGS

FIG. 1 is a circuit diagram showing a configuration of a bistable circuit included in a shift register in a gate driver of an active matrix-type liquid crystal display device according to a first embodiment of the present invention.

FIG. 2 is a block diagram showing an overall configuration of the liquid crystal display device in the first embodiment.

FIG. 3 is a block diagram for describing a configuration of the gate driver in the first embodiment.

FIG. 4 is a block diagram showing a configuration of the shift register in the gate driver in the first embodiment.

FIGS. 5A to 5H are timing charts of input and output signals of the shift register in the first embodiment.

FIGS. 6A to 6G are timing charts for describing the operation of each stage (bistable circuit) of the shift register in the first embodiment.

FIG. 7 is a circuit diagram showing a state in which a thin film transistor T6 is diode-connected in the first embodiment.

FIG. 8 is a block diagram showing a configuration of a shift register in a gate driver in a second embodiment of the present invention.

FIG. 9 is a circuit diagram showing a configuration of a bistable circuit in the second embodiment.

FIGS. 10A to 10H are timing charts for describing the operation of each stage (bistable circuit) of the shift register in the second embodiment.

FIG. 11 is a block diagram showing a configuration of a shift register in a gate driver in a third embodiment of the present invention.

FIG. 12 is a circuit diagram showing a configuration of a bistable circuit in the third embodiment.

FIGS. 13A to 13H are timing charts for describing the operation of each stage (bistable circuit) of the shift register in the third embodiment.

FIG. 14 is a block diagram showing a configuration of a shift register in a gate driver in a fourth embodiment of the present invention.

FIG. 15 is a circuit diagram showing a configuration of a bistable circuit in the fourth embodiment.

FIGS. 16A to 16I are timing charts for describing the operation of each stage (bistable circuit) of the shift register in the fourth embodiment.

FIG. 17 is a circuit diagram showing a configuration of a bistable circuit in a variant of the second embodiment.

FIG. 18 is a circuit diagram showing a configuration of a bistable circuit in a variant of the fourth embodiment.

FIG. 19 is a block diagram showing an exemplary configuration of a shift register in a gate driver in a conventional example.

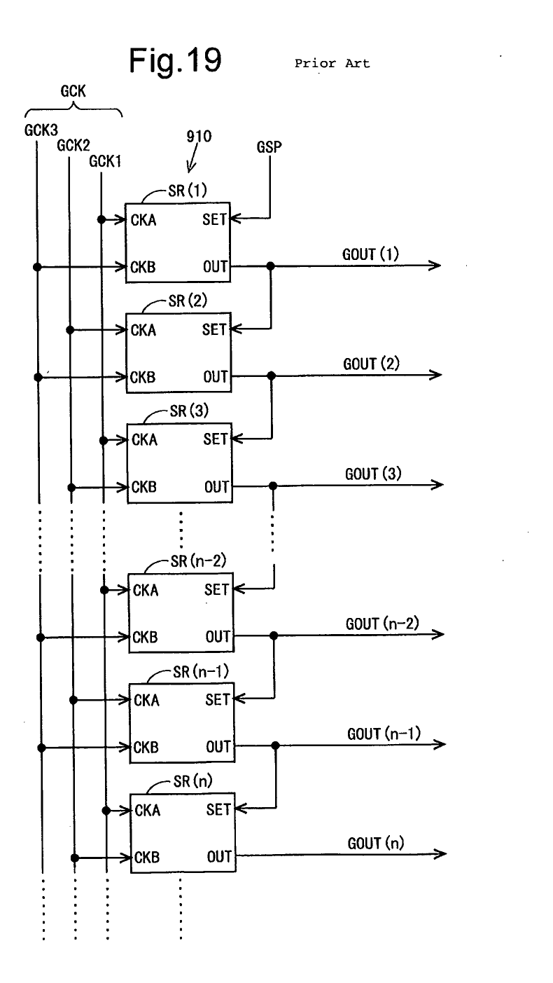

FIG. 20 is a circuit diagram showing an exemplary configuration of a bistable circuit in the conventional example.

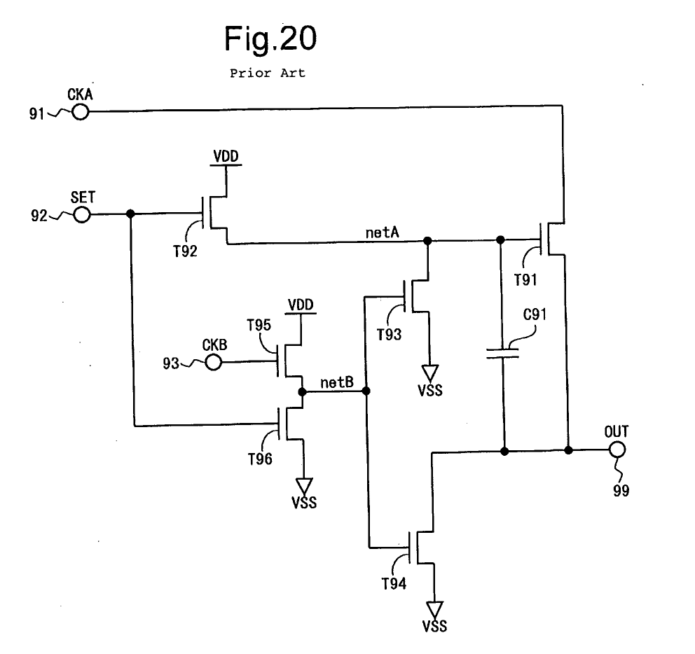

FIGS. 21A to 21G are timing charts of input and output signals of the shift register in the conventional example.

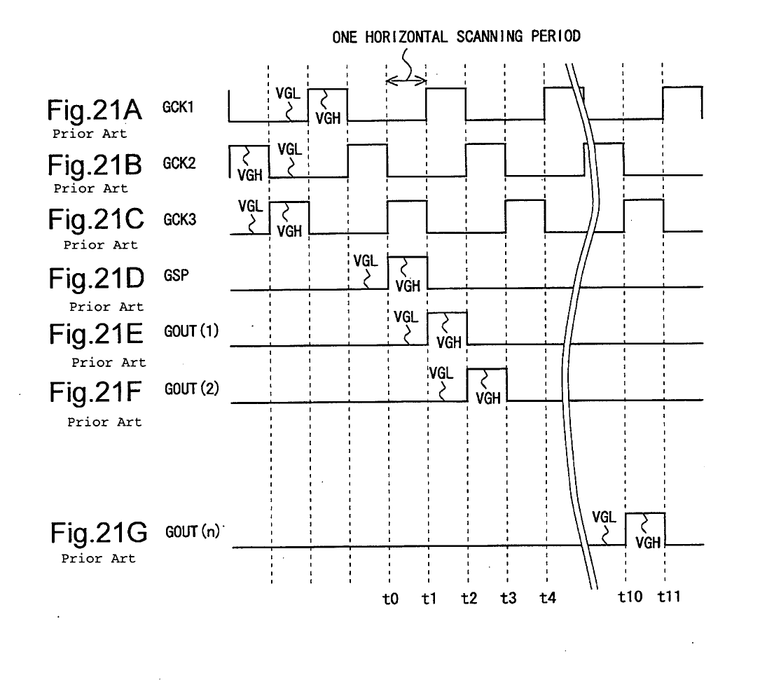

FIGS. 22A to 22F are timing charts for describing the operation of each stage (bistable circuit) of the shift register in the conventional example.

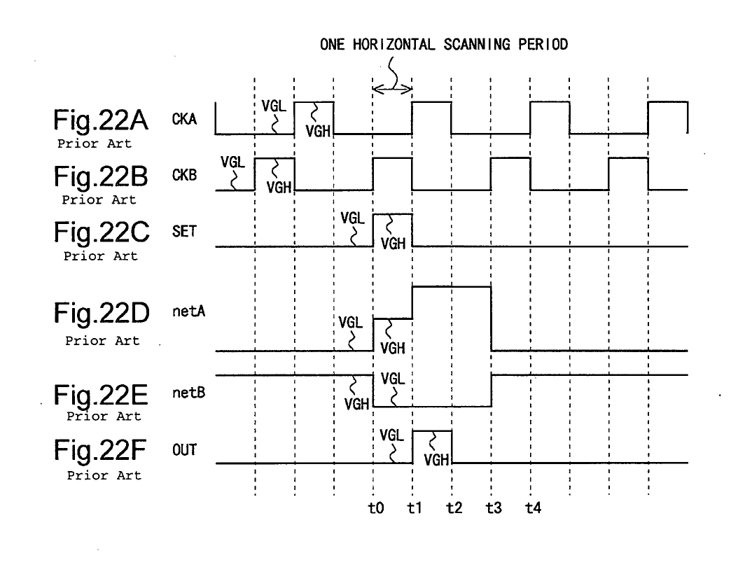

### MODE FOR CARRYING OUT THE INVENTION

Embodiments of the present invention will be described below with reference to the accompanying drawings. Note that in the following description, a gate terminal (gate electrode) of a thin film transistor corresponds to a first electrode, a drain terminal (drain electrode) corresponds to a second electrode, and a source terminal (source electrode) corresponds to a third electrode.

### 1. First Embodiment

<1.1 Overall Configuration and Operation>

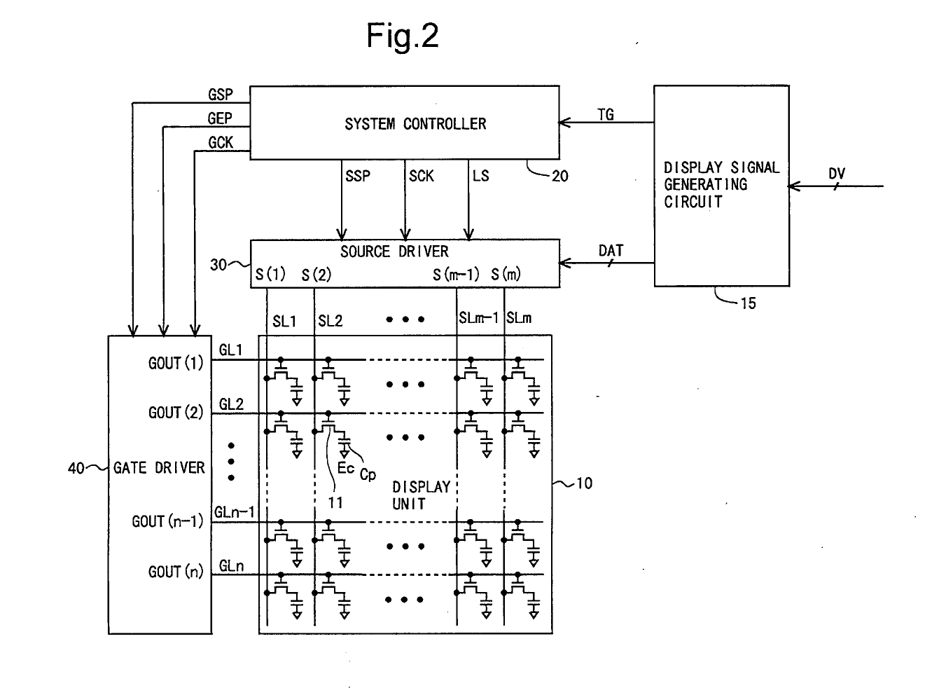

FIG. 2 is a block diagram showing an overall configuration of an active matrix-type liquid crystal display device according to a first embodiment of the present invention. As shown in FIG. 2, the liquid crystal display device includes a display unit 10, a display signal generating circuit 15, a system controller 20, a source driver (video signal line drive circuit) 30, and a gate driver (scanning signal line drive circuit) 40.

The display unit 10 includes a plurality of (m) source bus lines (video signal lines) SL1 to SLm; a plurality of (n) gate bus lines (scanning signal lines) GL1 to GLn; and a plurality of (n×m) pixel formation portions provided at the respective intersections of the source bus lines SL1 to SLm and the gate bus lines GL1 to GLn.

The plurality of pixel formation portions are arranged in a matrix form and thereby form a pixel array. Each pixel formation portion is composed of a thin film transistor (TFT) 11 which is a switching element having a gate terminal connected to a gate bus line passing through a corresponding intersection, and having a source terminal connected to a source bus line passing through the intersection; a pixel electrode connected to a drain terminal of the thin film transistor 11; a common electrode Ec which is a counter electrode provided so as to be shared by the plurality of pixel formation portions; and a liquid crystal layer provided so as to be shared by the plurality of pixel formation portions, and sandwiched between the pixel electrode and the common electrode Ec. By a liquid crystal capacitance formed by the pixel electrode and the common electrode Ec, a pixel capacitance Cp is formed. Note that normally, in order to securely hold a voltage in the pixel capacitance Cp, an auxiliary capacitance is provided in parallel to the liquid crystal capacitance; however, since the auxiliary capacitance is not directly related to the present invention, the description and depiction thereof are omitted.

The display signal generating circuit 15 receives a digital video signal DV sent from an external source and extracts luminance grayscale signal components and timing signal components from the digital video signal DV. Then, the display signal generating circuit 15 provides the luminance grayscale signal components to the source driver 30 as display data DAT and provides the timing signal components to the system controller 20 as a timing signal TG.

The system controller 20 generates a source start pulse signal SSP, a source clock signal SCK, a latch strobe signal LS, a gate start pulse signal GSP, a gate end pulse signal GEP, and a gate clock signal GCK which are for controlling image display on the display unit 10, based on the timing signal TG outputted from the display signal generating circuit 15, and outputs the signals.

The source driver 30 receives the display data DAT outputted from the display signal generating circuit 15 and the source start pulse signal SSP, the source clock signal SCK, and the latch strobe signal LS which are outputted from the system controller 20, and applies driving video signals S(1) to S(m) to the source bus lines SL1 to SLm, respectively.

The gate driver 40 repeats application of active scanning signals GOUT(1) to GOUT(n) to the respective gate bus lines GL1 to GLn in cycles of one vertical scanning period, based on the gate start pulse signal GSP, the gate end pulse signal GEP, and the gate clock signal GCK which are outputted from the system controller 20. Note that a detailed description of the gate driver 40 will be made later.

In the above-described manner, the driving video signals S(1) to S(m) are applied to the source bus lines SL1 to SLm, respectively, and the scanning signals GOUT(1) to GOUT(n) are applied to the gate bus lines GL1 to GLn, respectively, whereby an image based on the digital video signal DV sent from the external source is displayed on the display unit 10.

<1.2 Configuration and Operation of the Gate Driver>

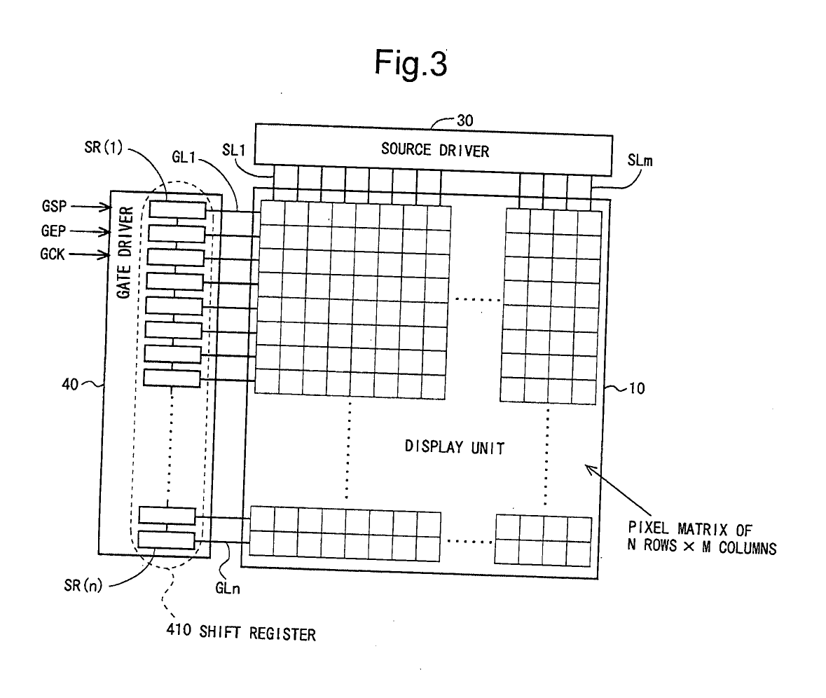

Next, with reference to FIGS. 3, 4, and 5A to 5H, an overview of the configuration and operation of the gate driver 40 of the present embodiment will be described. As shown in FIG. 3, the gate driver 40 is composed of an n-stage shift register 410. In the display unit 10, a pixel matrix of n rows×m columns is formed, and the stages of the shift register 410 are provided so as to have a one-to-one correspondence with the rows of the pixel matrix. Each stage of the shift register 410 is a bistable circuit which is in either one of two states (a first state and a second state) at each time point and which outputs a signal (state signal) indicating the state, as a scanning signal. As such, the shift register 410 is composed of n bistable circuits SR(1) to SR(n). Note that, in the present embodiment, when a bistable circuit is in the first state, a gate bus line connected to the bistable circuit is placed in a selected state, and when a bistable circuit is in the second state, a gate bus line connected to the bistable circuit is placed in a non-selected state.

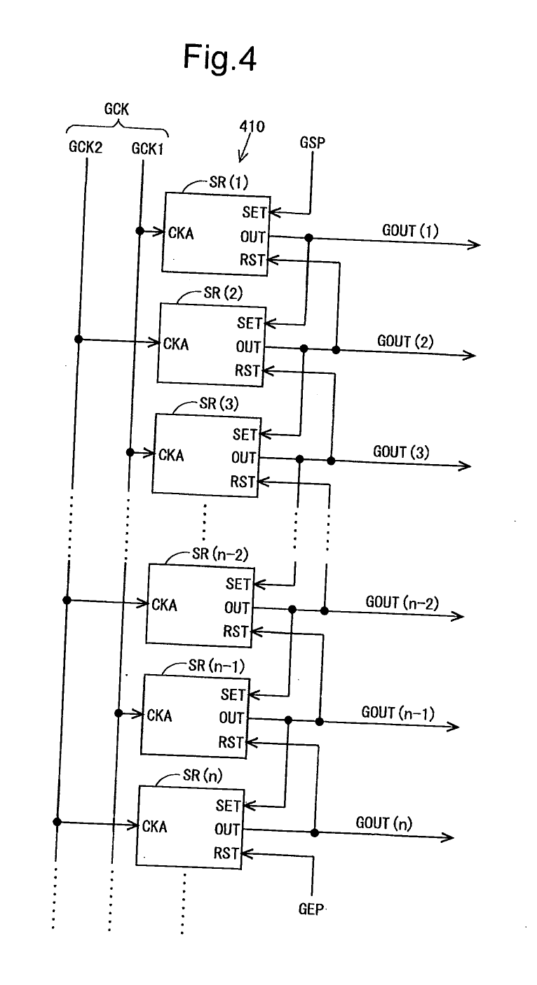

FIG. 4 is a block diagram showing a configuration of the shift register 410 in the gate driver 40. As described above, the shift register 410 is composed of the n bistable circuits SR(1) to SR(n). As shown in FIG. 4, to the shift register 410 are provided two-phase gate clock signals GCK1 (hereinafter, referred to as a “first gate clock signal”) and GCK2 (hereinafter, referred to as a “second gate clock signal”), a gate start pulse signal GSP which is a signal for starting scanning of the gate bus lines, and a gate end pulse signal GEP which is a signal for terminating scanning of the gate bus lines. Each bistable circuit is provided with an input terminal for receiving either one of the first gate clock signal GCK1 and the second gate clock signal GCK2 as a first clock CKA; an input terminal for receiving the gate start pulse signal GSP or a state signal OUT outputted from its previous stage, as a set signal SET (first instruction signal); an input terminal for receiving the gate end pulse signal GEP or a state signal OUT outputted from its subsequent stage, as a reset signal RST (second instruction signal); and an output terminal for outputting a state signal OUT as a scanning signal GOUT. Note that the first gate clock signal GCK1 and the second gate clock signal GCK2 are shifted in phase from each other by 180 degrees.

In the present embodiment, signals provided to the input terminals of each stage (each bistable circuit) are as follows. For the bistable circuit SR(1) of the first stage, a first gate clock signal GCK1 is provided as a first clock CKA, a gate start pulse signal GSP is provided as a set signal SET, and a state signal OUT from its subsequent stage is provided as a reset signal RST. For the bistable circuit SR(2) of the second stage, a second gate clock signal GCK2 is provided as a first clock CKA, a state signal OUT from its previous stage is provided as a set signal SET, and a state signal OUT from its subsequent stage is provided as a reset signal RST. For the bistable circuit SR(3) of the third stage, the first gate clock signal GCK1 is provided as a first clock CKA, a state signal OUT from its previous stage is provided as a set signal SET, and a state signal OUT from its subsequent stage is provided as a reset signal RST. For the bistable circuits SR(4) to SR(n−1) of the fourth to (n−1)th stages, the same configurations as the above-described configurations of the second and third stages are repeated every two stages. For the bistable circuit SR(n) of the nth stage, the second gate clock signal GCK2 is provided as a first clock CKA, a state signal OUT from its previous stage is provided as a set signal SET, and a gate end pulse signal GEP is provided as a reset signal RST.

Next, a signal outputted from the output terminal of each stage (each bistable circuit) will be described. A state signal OUT outputted from the bistable circuit SR(1) of the first stage serves as a scanning signal GOUT(1) for placing the gate bus line GL1 of the first row in a selected state, and is provided to the bistable circuit SR(2) of the second stage as a set signal SET. A state signal OUT outputted from the bistable circuit SR(n) of the nth stage serves as a scanning signal GOUT(n) for placing the gate bus line GLn of the nth row in a selected state, and is provided to the bistable circuit SR(n−1) of the (n−1)th stage as a reset signal RST. State signals OUT outputted from other stages serve as scanning signals for placing gate bus lines of their corresponding rows in a selected state, and are provided to their respective subsequent stages as set signals SET, and provided to their respective previous stages as reset signals RST.

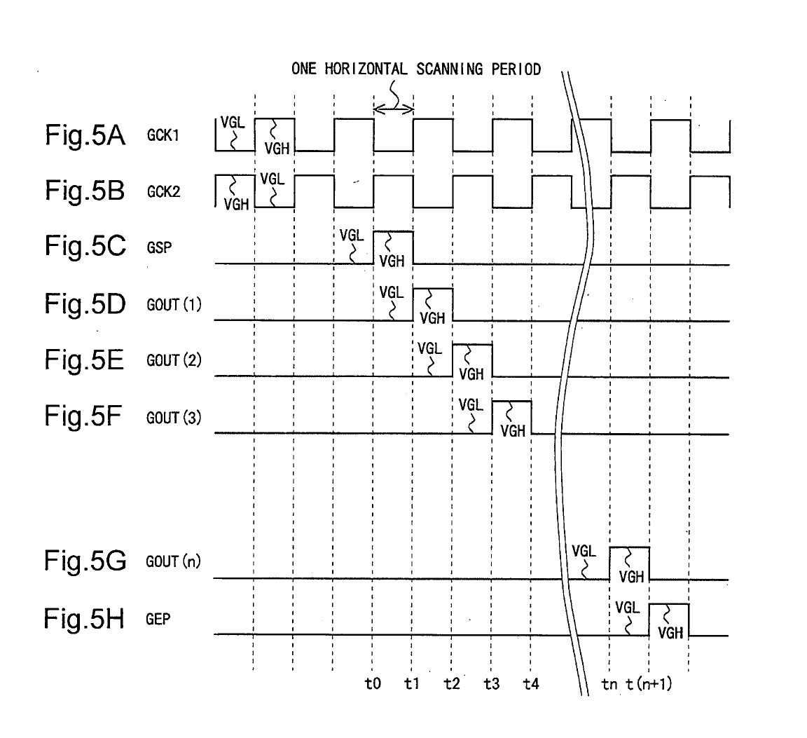

FIGS. 5A to 5H are timing charts of input and output signals of the shift register 410 in the present embodiment. During the operation of the liquid crystal display device, a first gate clock signal GCK1 and a second gate clock signal GCK2 which are shifted in phase from each other by 180 degrees as shown in FIGS. 5A and 5B are provided to the shift register 410 in the gate driver 40. When reaching time point to, a pulse of a gate start pulse signal GSP is provided to the bistable circuit SR(1) of the first stage in the shift register 410. Based on the pulse, the bistable circuit SR(1) of the first stage operates in a manner described later, and at time point t1, a state signal outputted from the bistable circuit SR(1) of the first stage goes to a high level. For the second and subsequent stages, based on state signals outputted from the previous stages of the respective stages, state signals outputted from the respective stages go to a high level. By this, as shown in FIGS. 5D to 5G, state signals which sequentially go to a high level for one horizontal scanning period are provided to the gate bus lines GL1 to GLn in the display unit 10, as scanning signals GOUT(1) to GOUT(n). After a state signal outputted from the bistable circuit SR(n) of the nth stage goes to a high level at time point tn, when reaching time point t(n+1), a pulse of a gate end pulse signal GEP is provided to the bistable circuit SR(n) of the nth stage in the shift register 410. By this, the operation for performing image display for one frame is completed.

<1.3 Configuration of the Bistable Circuit>

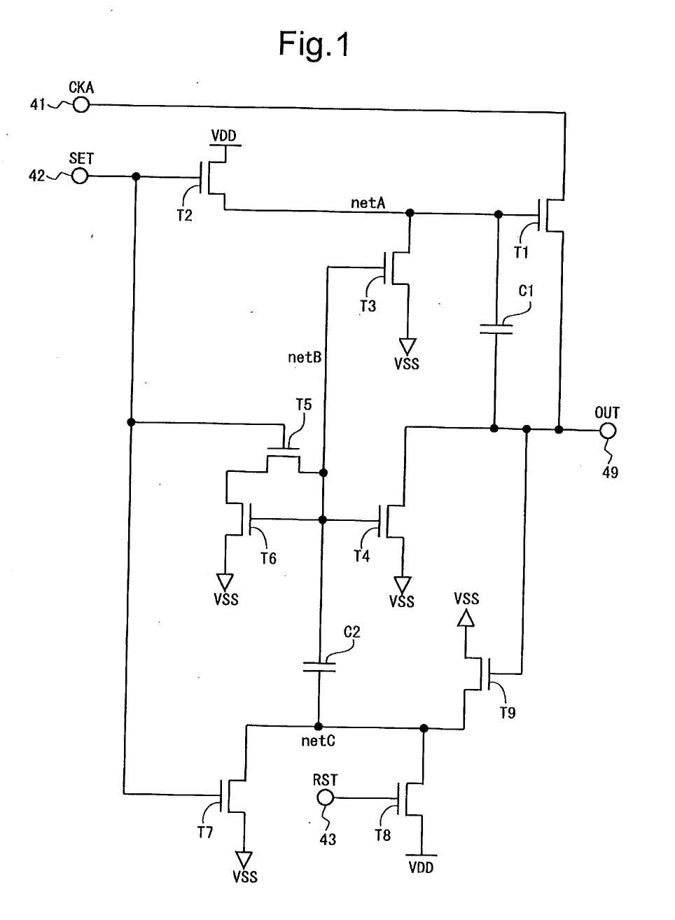

FIG. 1 is a circuit diagram showing a configuration of a bistable circuit included in the above-described shift register 410 (a configuration for one stage of the shift register 410). As shown in FIG. 1, the bistable circuit includes nine thin film transistors (here, n-type TFTs) T1 to T9 (first to ninth transistors); and capacitors C1 and C2. The thin film transistors T1 to T9 are not particularly limited but, for example, amorphous silicon TFTs, low-temperature polysilicon TFTs, CG (Continuous Grain) silicon TFTs, etc., are employed. In addition, the bistable circuit has input terminals for a power supply line VDD which supplies a relatively high-level potential VGH and input terminals for a power supply line VSS which supplies a relatively low-level potential VGL, and three input terminals 41 to 43 and one output terminal (output node) 49. The potential VGH corresponds to a potential that places a thin film transistor 11 in a pixel formation portion in the display unit 10 in an on state, and the potential VGL corresponds to a potential that places the thin film transistor 11 in an off state. Note that the input terminal that receives a first clock CKA is denoted by reference numeral 41, the input terminal that receives a set signal SET is denoted by reference numeral 42, and the input terminal that receives a reset signal RST is denoted by reference numeral 43. A connection relationship between the components in the bistable circuit will be described below.

A gate terminal of the thin film transistor T1, a source terminal of the thin film transistor T2, and a drain terminal of the thin film transistor T3 are connected to one another. Note that a region (wiring line) where they are connected to one another is referred to as a “netA” (first node) for convenience's sake. Agate terminal of the thin film transistor T3, a gate terminal of the thin film transistor T4, a drain terminal of the thin film transistor T5, and a gate terminal of the thin film transistor T6 are connected to one another. Note that a region (wiring line) where they are connected to one another is referred to as a “netB” (second node) for convenience's sake. A drain terminal of the thin film transistor T7, a source terminal of the thin film transistor T8, and a drain terminal of the thin film transistor T9 are connected to one another. Note that a region (wiring line) where they are connected to one another is referred to as a “netC” (third node) for convenience's sake.

For the thin film transistor T1, the gate terminal is connected to the netA, the drain terminal is connected to the input terminal 41, and the source terminal is connected to the output terminal 49. For the thin film transistor T2, the gate terminal is connected to the input terminal 42, the drain terminal is connected to the power supply line VDD, and the source terminal is connected to the netA. For the thin film transistor T3, the gate terminal is connected to the netB, the drain terminal is connected to the netA, and the source terminal is connected to the power supply line VSS. For the thin film transistor T4, the gate terminal is connected to the netB, the drain terminal is connected to the output terminal 49, and the source terminal is connected to the power supply line VSS. For the thin film transistor T5, the gate terminal is connected to the input terminal 42, the drain terminal is connected to the netB, and the source terminal is connected to the drain terminal of the thin film transistor T6. For the thin film transistor T6, the gate terminal is connected to the netB, the drain terminal is connected to the source terminal of the thin film transistor T5, and the source terminal is connected to the power supply line VSS. For the thin film transistor T7, the gate terminal is connected to the input terminal 42, the drain terminal is connected to the netC, and the source terminal is connected to the power supply line VSS. For the thin film transistor T8, the gate terminal is connected to the input terminal 43, the drain terminal is connected to the power supply line VDD, and the source terminal is connected to the netC. For the thin film transistor T9, the gate terminal is connected to the output terminal 49, the drain terminal is connected to the netC, and the source terminal is connected to the power supply line VSS. For the capacitor C1, one end is connected to the netA and the other end is connected to the output terminal 49. For the capacitor C2, one end is connected to the netB and the other end is connected to the netC.

The thin film transistors T3, T4, and T6 are designed to have the same transistor characteristics. Regarding this, for example, the thin film transistors T3, T4, and T6 are configured to have an equal W/L ratio (the ratio of the channel width to the channel length), and at least one of the thin film transistors T3 and T4 is disposed to be close to the thin film transistor T6. In addition, in the present embodiment, it is assumed that the thin film transistors T3, T4, and T6 have the same initial threshold voltage (threshold voltage immediately before operating the circuit) and also have the same amount of shift in threshold voltage after operating the circuit in a given period.

Note that, in the present embodiment, by the thin film transistor T2, a first node charging portion is implemented, and by the thin film transistors T5, T6, T7, T8, and T9 and the capacitor C2, a second node potential control portion is implemented. Note also that by the thin film transistors T5 and T6, a second node potential low-level setting portion is implemented, and by the thin film transistors T7, T8, and T9 and the capacitor C2, a second node potential high-level setting portion is implemented. Furthermore, by the thin film transistor T8, a third node charging portion is implemented.

<1.4 Operation of the Shift Register>

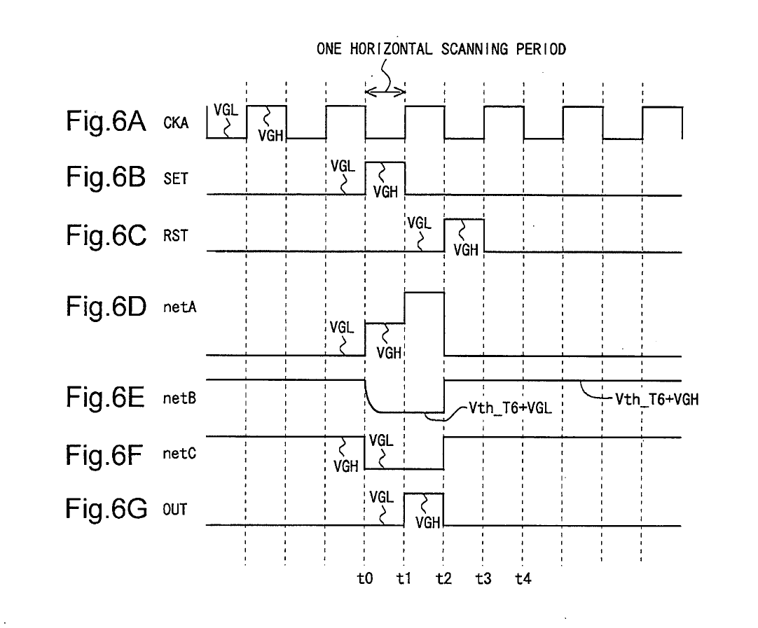

Next, with reference to FIGS. 1 and 6A to 6G, the operation of each stage (bistable circuit) of the shift register 410 in the present embodiment will be described. Note that FIGS. 6A to 6G show waveforms for the bistable circuit SR(1) of the first stage, and for the bistable circuits SR(2) to SR(n) of the second and subsequent stages, the same waveforms as those shown in FIGS. 6A to 6G appear with a delay of one horizontal scanning period. Namely, the n bistable circuits SR(1) to SR(n) perform the same operation with the exception of timing. Accordingly, in the following, description will be made focusing only on the bistable circuit SR(1) of the first stage.

During the operation of the display device, a first clock CKA having a waveform shown in FIG. 6A is provided to the input terminal 41. During a period before time point t0, the potentials of a set signal SET, a reset signal RST, a netA, and a state signal OUT are VGL, the potential of a netB is “Vth_T6+VGH”, and the potential of a netC is VGH. Note that Vth_T6 is the threshold voltage of the thin film transistor T6 and the following equations (2) and (3) are established:

Vth_T6>0 (2)

Vth_T6>VGL (3).

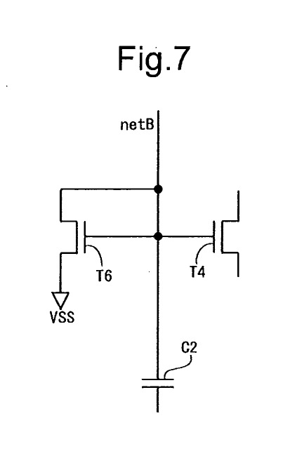

When reaching time point to, a pulse of the set signal SET is provided to the input terminal 42. By this, the thin film transistors T2, T5, and T7 are placed in an on state. By the thin film transistor T2 being placed in an on state, the potential of the netA increases to the potential VGH of the power supply line VDD and thus the thin film transistor T1 is placed in an on state. Since the potential of the first clock CKA is VGL during the period from t0 to t1, during this period, the potential of the state signal OUT is maintained at VGL. In addition, by the thin film transistor T7 being placed in an on state, the potential of the netC is brought to VGL. Furthermore, by the thin film transistor T5 being placed in an on state, the gate and drain terminals of the thin film transistor T6 are placed in a short-circuit state. Namely, as shown in FIG. 7, the thin film transistor T6 has a configuration equivalent to a diode-connected configuration. By this, a current flows from the netB to the source terminal of the thin film transistor T6 and thus the potential of the netB decreases to “Vth_T6+VGL”.

When the potential of the netB decreases to “Vth_T6+VGL” during the period from t0 to t1, a gate-source voltage Vgs of the thin film transistor T6 is brought to Vth_T6 and thus the thin film transistor T6 is placed in an off state. In addition, since, as described above, the threshold voltages of the thin film transistors T3, T4, and T6 are equal, the thin film transistors T3 and T4 are also placed in an off state. Since the thin film transistor T3 is placed in an off state as described above, the potential of the netA increased at time point t0 does not decrease before time point t1. Note that the above-described Vth_T6 is a reference threshold voltage in the current frame period in this bistable circuit.

When reaching time point t1, the potential of the set signal SET changes from VGH to VGL. By this, the thin film transistors T2, T5, and T7 are placed in an off state. In addition, at time point t1, the potential of the first clock CKA changes from VGL to VGH. By this, the drain potential of the thin film transistor T1 increases with the increase in the potential of the input terminal 41. At this time, since the thin film transistor T1 is in an on state, the potential of the netA further increases from VGH through a parasitic capacitance between the gate and drain of the thin film transistor T1. As a result, a high voltage is applied to the gate terminal of the thin film transistor T1 and thus the potential of the state signal OUT increases to the potential VGH of the first clock CKA. By this, a gate bus line connected to the output terminal 49 of this bistable circuit is placed in a selected state. When the potential of the output terminal 49 increases and accordingly the voltage between the gate and source of the thin film transistor T9 becomes higher than the threshold voltage of the thin film transistor T9, the thin film transistor T9 is placed in an on state. By this, the potential of the netC is maintained at VGL. Here, since one end of the capacitor C2 is connected to the netB and the other end is connected to the netC, the netB also maintains its potential obtained immediately before time point t1. Accordingly, during the period from t1 to t2, the thin film transistors T3 and T4 are placed in an off state and thus the potential of the netA and the potential of the state signal OUT do not decrease.

When reaching time point t2, the potential of the first clock CKA changes from VGH to VGL. Since the potential of the netA is higher than VGH at the time point immediately before time point t2, when the drain potential of the thin film transistor T1 decreases with the decrease in the potential of the input terminal 41, a current flows from the source terminal to the drain terminal of the thin film transistor T1. By this, the potential of the output terminal 49, i.e., the potential of the state signal OUT, decreases to VGL. Accordingly, the gate bus line connected to the output terminal 49 of this bistable circuit is placed in a non-selected state. In addition, by the potential of the output terminal 49 decreasing to VGL, the thin film transistor T9 is placed in an off state,

In addition, at time point t2, a pulse of a state signal OUT outputted from a bistable circuit of a subsequent stage of this bistable circuit is provided to the input terminal 43 of this bistable circuit as a pulse of the reset signal RST. By this, the thin film transistor T8 is placed in an on state and thus the potential of the netC increases from VGL to VGH. Since, as described above, one end of the capacitor C2 is connected to the netB and the other end is connected to the netC, with the increase in the potential of the netC, the potential of the netB also increases by “VGH−VGL”. Accordingly, at and after time point t2, the potential of the netB is “Vth_T6+VGH”. By this, the thin film transistors T3 and T4 are placed in an on state. By the thin film transistor T3 being placed in an on state, the potential of the netA is brought to VGL and thus the thin film transistor T1 is placed in an off state. In addition, by the thin film transistor T4 being placed in an on state, the potential of the state signal OUT is brought to VGL.

When reaching time point t3, the potential of the first clock CKA changes from VGL to VGH. In addition, at time point t3, the potential of the reset signal RST changes from VGH to VGL. Here, the potential of the set signal SET is maintained at VGL at and after time point t1. Hence, at and after time point t1, the thin film transistors T2, T5, and T7 are in an off state. The potential of the state signal OUT is maintained at VGL at and after time point t2. Hence, at and after time point t2, the thin film transistor T9 is in an off state. Accordingly, the netB and the netC maintain their potentials obtained immediately before time point t3, at and after time point t3, too. By this, the thin film transistor T3 is maintained in an on state and the potential of the netA is maintained at VGL. Hence, the thin film transistor T1 is maintained in an off state and regardless of the increase in the potential of the first clock CKA, the potential of the state signal OUT is maintained at VGL. Then, during a period before reaching time point t0 of the next frame period, the netA, the netB, the netC, and the state signal OUT maintain their potentials obtained at time point t3.

The operation such as that described above is sequentially performed by the above-described n bistable circuits SR(1) to SR(n) such that the timing is delayed by one horizontal scanning period. By this, in each frame period, the n gate bus lines GL1 to GLn are sequentially placed in a selected state for one horizontal scanning period.

<1.5 Effect>

According to the present embodiment, the potential of the netB in each bistable circuit composing the shift register 410 is maintained at “Vth_T6+VGH” during most periods in each frame period (each vertical scanning period). Hence, the threshold voltages of the thin film transistors T3, T4, and T6 shift in a positive direction. However, unlike the conventional example, the drive capability of the thin film transistors does not decrease. The reason for such will be described below.

When the above equation (1) is applied to the thin film transistor T6 in the present embodiment, the above equation (1) is represented by the following equation (4):

Ids=(W/L)×μ×Cox×(Vgs−Vth_{—}T6−(Vds/2))×Vds (4).

Here, since the potential of the netB is “Vth_T6+VGH” during most periods in each frame period, by substituting (Vth_T6+VGH−VGL) for Vgs in the above equation (4), the following equation (5) is established. Note that the reason that (Vth_T6+VGH−VGL) is substituted for Vgs is because the gate potential of the thin film transistor T6 is “Vth_T6+VGH” and the source potential is VGL.

$$\begin{matrix}Ids = ( W / L ) \times μ \times Cox \times ( \begin{matrix}( Vth\_T6 + VGH - VGL ) - \\ Vth\_T6 - ( Vds / 2 )\end{matrix} ) \times Vds \\ = ( W / L ) \times μ \times Cox \times ( VGH - VGL - ( Vds / 2 ) ) \times Vds\end{matrix} \qquad ( 5 )$$

It is understood from the above equation (5) that a drain-source current Ids of the thin film transistor T6 is determined independent of the magnitude of the threshold voltage of the thin film transistor T6. Accordingly, even if a shift occurs in the threshold voltage of the thin film transistor T6, the drive capability of the thin film transistor T6 does not decrease. In addition, since the thin film transistors T3 and T4 are designed to have the same transistor characteristics as the thin film transistor T6, the drive capability of the thin film transistors T3 and T4 does not decrease either, even if a shift occurs in threshold voltage. Due to the above, the occurrence of abnormal operation of the display device resulting from a shift in the threshold voltage of a thin film transistor is prevented.

### 2. Second Embodiment

<2.1 Overall Configuration and Configuration of a Gate Driver>

In the present embodiment, an overall configuration and a schematic configuration of a gate driver are substantially the same as those in the above-described first embodiment which are shown in FIGS. 2 and 3, and thus, a detailed description thereof is omitted. Note, however, that in the present embodiment an initialization signal INI is sent to a gate driver 40 from a system controller 20, in addition to the signals in the first embodiment.

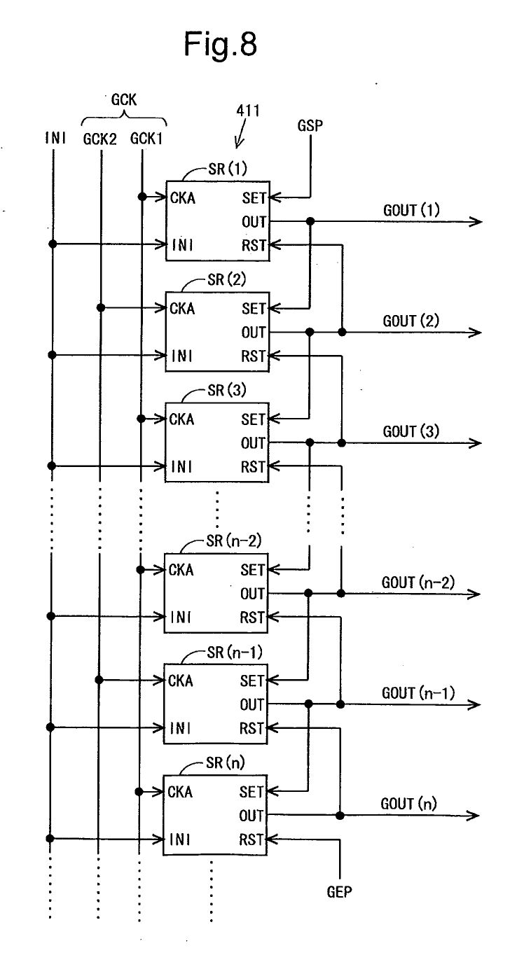

FIG. 8 is a block diagram showing a configuration of a shift register 411 in the gate driver 40 in the present embodiment. As shown in FIG. 8, each of bistable circuits SR(1) to SR(n) is provided with an input terminal for receiving an initialization signal INI, in addition to the input terminals in the first embodiment.

<2.2 Configuration of the Bistable Circuit>

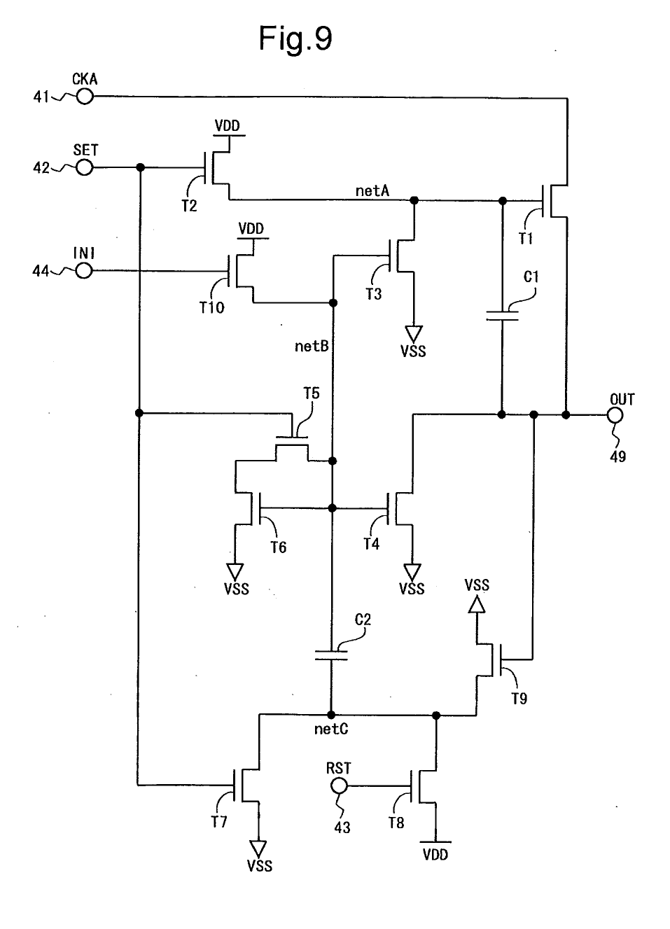

FIG. 9 is a circuit diagram showing a configuration of a bistable circuit in the present embodiment. In the present embodiment, a thin film transistor T10 (tenth transistor) and an input terminal 44 that receives an initialization signal INI are provided in addition to the components in the first embodiment which are shown in FIG. 1. For the thin film transistor T10, the gate terminal is connected to the input terminal 44, the drain terminal is connected to a power supply line VDD, and a source terminal is connected to a netB. Note that by the thin film transistor T10, a second node initialization portion is implemented.

<2.3 Operation of the Shift Register>

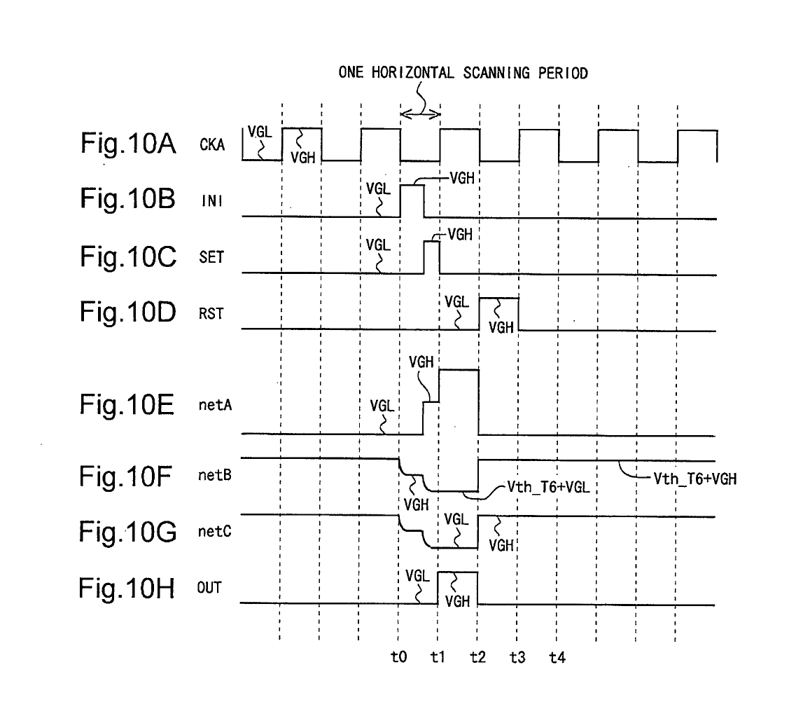

Next, with reference to FIGS. 9 and 10A to 10H, the operation of the shift register 411 in the present embodiment will be described. Note that only different points from the first embodiment will be described in detail and the same points as those in the first embodiment will be briefly described. As shown in FIG. 10B, when reaching time point to, a pulse of an initialization signal INI is provided to the input terminals 44 of all of the bistable circuits SR(1) to SR(n) composing the shift register 411. By this, in all of the bistable circuits SR(1) to SR(n), the thin film transistors T10 are placed in an on state and thus the potentials of the netBs are brought to VGH. Hence, thin film transistors T3 and T4 are placed in an on state. By the thin film transistors T3 being placed in an on state, the potentials of netAs are brought to VGL. In addition, by the thin film transistors T4 being placed in an on state, the potentials of state signals OUT are brought to VGL. Thereafter, by providing a pulse of a set signal SET to an input terminal 42 of the bistable circuit SR(1) of the first stage, the same operation as that at time point t0 in the first embodiment is performed. Note that a pulse of a gate start pulse signal GSP (the set signal SET for the bistable circuit of the first stage) occurs at timing later than that in the first embodiment. At and after time point t1, the same operation as that in the first embodiment is performed; Note that since, as described above, a pulse of the initialization signal INI is provided to all of the bistable circuits SR(1) to SR(n) at the same timing, the period during which the potential of the netB is maintained at VGH is relatively short for those bistable circuits close to the first stage, and is relatively long for those bistable circuits close to the nth stage.

<2.4 Effects>

According to the present embodiment, as with the first embodiment, even if a shift in threshold voltage occurs in a thin film transistor composing the shift register 411, the drive capability of the thin film transistor does not decrease. In addition, according to the present embodiment, in all of the bistable circuits SR(1) to SR(n), the potentials of the netBs are securely brought to VGH and the potentials of the netAs and the potentials of the state signals OUT are securely brought to VGL every frame period. Since the states of the netBs, the netAs, and the state signals OUT are thus initialized every frame period, the operation of the shift register 411 is stabilized. In general, immediately after turning on the power to a display device, the potential of each node in a shift register goes into an unstable state; however, according to the configuration according to the present embodiment, the operation of the shift register is stabilized and thus the occurrence of abnormal operation of the display device is effectively prevented.

### 3. Third Embodiment

3.1 Overall Configuration and Configuration of a Gate Driver

In the present embodiment, an overall configuration and a schematic configuration of a gate driver are substantially the same as those in the above-described first embodiment which are shown in FIGS. 2 and 3, and thus, a detailed description thereof is omitted. Note, however, that in the present embodiment three-phase gate clock signals GCK1, GCK2, and GCK3 (hereinafter, referred to as a “third gate clock signal”) are sent to a gate driver 40 from a system controller 20, instead of two-phase gate clock signals. Note that the three-phase gate clock signals GCK1, GCK2, and GCK3 are shifted in phase from each other by 60 degrees.

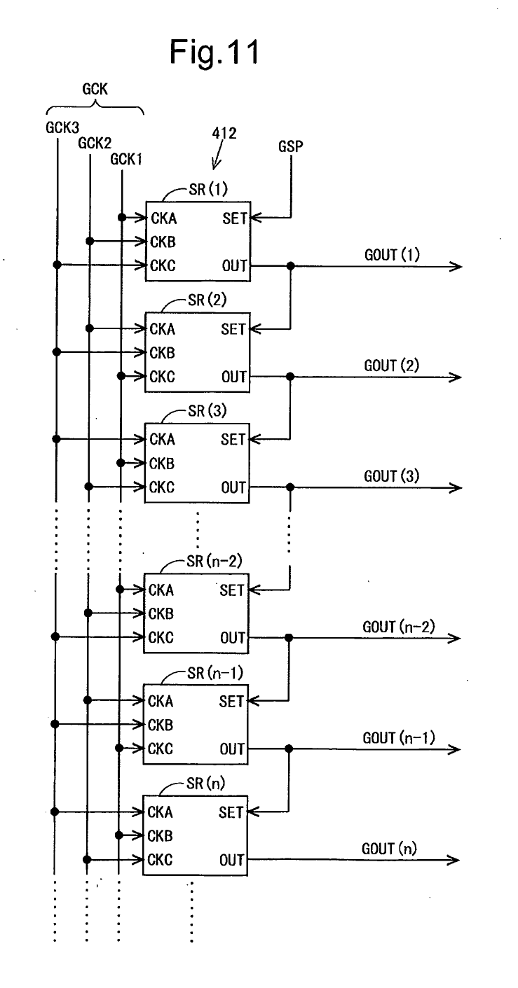

FIG. 11 is a block diagram showing a configuration of a shift register 412 in the gate driver 40 in the present embodiment. Each bistable circuit is provided with input terminals for receiving three-phase clock signals CKA, CKB, and CKC, an input terminal for receiving a gate start pulse signal GSP or a state signal OUT outputted from its previous stage, as a set signal SET, and an output terminal for outputting a state signal OUT as a scanning signal GOUT.

The above-described three-phase clock signals CKA, CKB, and CKC provided to each bistable circuit are as follows. For a bistable circuit SR(1) of the first stage, a first gate clock signal GCK1 is provided as a first clock CKA, a second gate clock signal GCK2 is provided as a second clock CKB, and a third gate clock signal GCK3 is provided as a third clock CKC. For a bistable circuit SR(2) of the second stage, the second gate clock signal GCK2 is provided as a first clock CKA, the third gate clock signal GCK3 is provided as a second clock CKB, and the first gate clock signal GCK1 is provided as a third clock CKC. For a bistable circuit SR(3) of the third stage, the third gate clock signal GCK3 is provided as a first clock CKA, the first gate clock signal GCK1 is provided as a second clock CKB, and the second gate clock signal GCK2 is provided as a third clock CKC. For the fourth and subsequent stages, the same configurations as those of the first to third stages are repeated every three stages.

<3.2 Configuration of the Bistable Circuit>

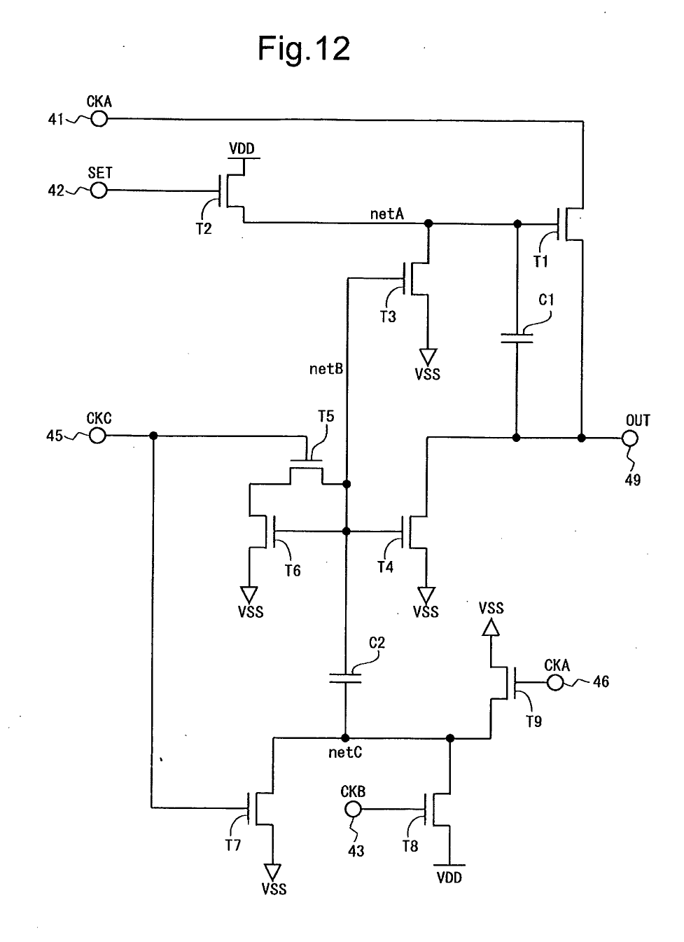

FIG. 12 is a circuit diagram showing a configuration of a bistable circuit in the present embodiment. In the present embodiment, an input terminal 45 that receives a third clock CKC and an input terminal 46 that receives a first clock CKA are provided in addition to the components in the above-described first embodiment which are shown in FIG. 1. A gate terminal of a thin film transistor T5 and a gate terminal of a thin film transistor T7 are connected to the input terminal 45, and a gate terminal of a thin film transistor T9 is connected to the input terminal 46. Note that in the present embodiment a second clock CKB is provided to an input terminal 43.

<3.3 Operation of the Shift Register>

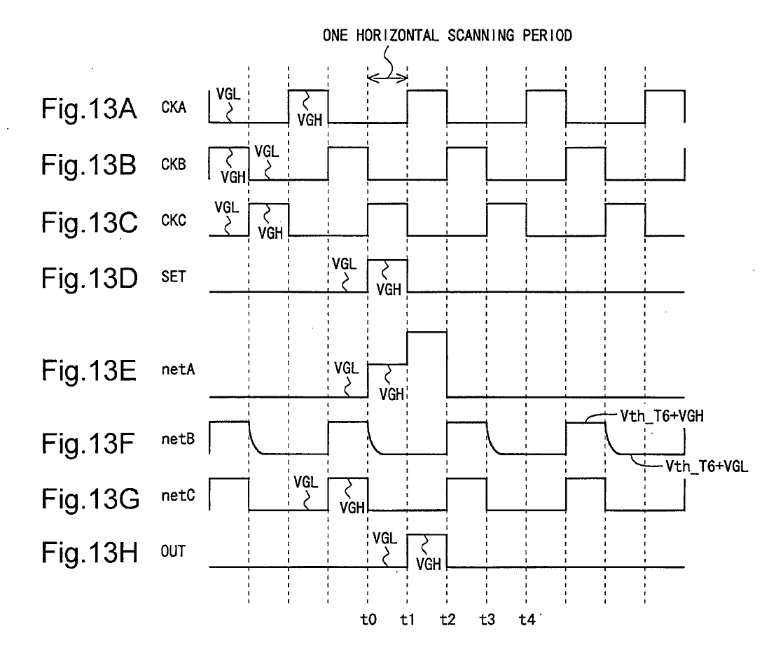

Next, with reference to FIGS. 12 and 13A to 13H, the operation of the shift register 412 in the present embodiment will be described. During the operation of a display device, a first clock CKA having a waveform shown in FIG. 13A is provided to input terminals 41 and 46, a second clock CKB having a waveform shown in FIG. 13B is provided to an input terminal 43, and a third clock CKC having a waveform shown in FIG. 13C is provided to an input terminal 45.

When reaching time point to, a pulse of a set signal SET is provided to the input terminal 42. By this, a thin film transistor T2 is placed in an on state. By the thin film transistor T2 being placed in an on state, the potential of a netA increases to the potential VGH of a power supply line VDD and thus a thin film transistor T1 is placed in an on state. Since the potential of the first clock CKA is VGL during the period from t0 to t1, during this period, the potential of a state signal OUT is maintained at VGL. In addition, at time point to, since the potential of the third clock CKC changes from VGL to VGH, thin film transistors T5 and T7 are placed in an on state. By the thin film transistor T7 being placed in an on state, the potential of a netC is brought to VGL. In addition, by the thin film transistor T5 being placed in anon state, the gate and drain terminals of a thin film transistor T6 are placed in a short-circuit state. Namely, as shown in FIG. 7, the thin film transistor T6 has a configuration equivalent to a diode-connected configuration. By this, a current flows from a netB to a source terminal of the thin film transistor T6 and thus the potential of the netB decreases to “Vth_T6+VGL”. Note that Vth_T6 is the threshold voltage of the thin film transistor T6 and, as with the first embodiment, the above equations (2) and (3) are established.

When the potential of the netB decreases to “Vth_T6+VGL” during the period from t0 to t1, a gate-source voltage Vgs of the thin film transistor T6 is brought to Vth_T6 and thus the thin film transistor T6 is placed in an off state. In addition, as with the first embodiment, since the threshold voltages of the thin film transistors T3, T4, and T6 are equal, the thin film transistors T3 and T4 are also placed in an off state. Since the thin film transistor T3 is thus placed in an off state, the potential of the netA increased at time point t0 does not decrease before time point t1.

When reaching time point t1, the potential of the set signal SET changes from VGH to VGL. By this, the thin film transistor T2 is placed in an off state. In addition, at time point t1, the potential of the first clock CKA changes from VGL to VGH. By this, with the increase in the potential of the input terminal 41, the drain potential of the thin film transistor T1 increases. At this time, since the thin film transistor T1 is in an on state, the potential of the netA further increases from VGH through a parasitic capacitance between the gate and drain of the thin film transistor T1. As a result, a high voltage is applied to the gate terminal of the thin film transistor T1 and thus the potential of the state signal OUT increases to the potential VGH of the first clock CKA. By this, a gate bus line connected to an output terminal 49 of this bistable circuit is placed in a selected state. In addition, by the potential of the first clock CKA changing from VGL to VGH, a thin film transistor T9 is placed in an on state. By this, the potential of the netC is maintained at VGL. Here, since one end of a capacitor C2 is connected to the netB and the other end is connected to the netC, the netB also maintains its potential obtained immediately before time point t1. Accordingly, during the period from t1 to t2, the thin film transistors T3 and T4 are placed in an off state and thus the potential of the netA and the potential of the state signal OUT do not decrease.

When reaching time point t2, the potential of the first clock CKA changes from VGH to VGL. Since the potential of the netA is higher than VGH at the time point immediately before time point t2, when the drain potential of the thin film transistor T1 decreases with the decrease in the potential of the input terminal 41, a current flows from the source terminal to drain terminal of the thin film transistor T1. By this, the potential of the output terminal 49, i.e., the potential of the state signal OUT, decreases to VGL. Accordingly, the gate bus line connected to the output terminal 49 of this bistable circuit is placed in a non-selected state.

In addition, at time point t2, the potential of the second clock CKB changes from VGL to VGH. By this, a thin film transistor T8 is placed in an on state. During the period from t2 to t3, the potentials of the first clock CKA and the third clock CKC are VGL. Hence, during this period, the thin film transistors T7 and T9 are placed in an off state. Due to the above, the potential of the netC increases from VGL to VGH. As with the first embodiment, since one end of the capacitor C2 is connected to the netB and the other end is connected to the netC, with the increase in the potential of the netC, the potential of the netB also increases by “VGH−VGL”. Accordingly, at and after time point t2, the potential of the netB is “Vth_T6+VGH”. By this, the thin film transistors T3 and T4 are placed in an on state and thus the potential of the netA and the potential of the state signal OUT are brought to VGL. By the potential of the netA being brought to VGL, the thin film transistor T1 is placed in an off state.

When reaching time point t3, the potential of the second clock CKB changes from VGH to VGL. By this, the thin film transistor T8 is placed in an off state. In addition, at time point t3, the potential of the third clock CKC changes from VGL to VGH. By this, the thin film transistors T5 and T7 are placed in an on state. By the thin film transistor T8 being placed in an off state and the thin film transistor T7 being placed in an on state, the potential of the netC is brought to VGL. By the thin film transistor T5 being placed in an on state, as with time point to, the potential of the netB decreases to “Vth_T6+VGL”.

The operation such as that described above is sequentially performed by the above-described n bistable circuits SR(1) to SR(n) such that the timing is delayed by one horizontal scanning period. By this, in each frame period, the n gate bus lines GL1 to GLn are sequentially placed in a selected state for one horizontal scanning period.

<3.4 Effect>

According to the present embodiment, as shown in FIG. 13F, the period during which the potential of the netB is “Vth_T6+VGH” is substantially one-third of that in the above-described first embodiment. Namely, the on-duty of each of the thin film transistors T3, T4, and T6 (the percentage of a period during which the thin film transistor is placed in an on state) is substantially one-third. Hence, a shift in threshold voltage in a positive direction for the thin film transistors T3, T4, and T6 is suppressed compared to that in the first embodiment. By this, the occurrence of abnormal operation of the display device resulting from a shift in the threshold voltage of a thin film transistor is more effectively prevented.

### 4. Fourth Embodiment

<4.1 Configuration>

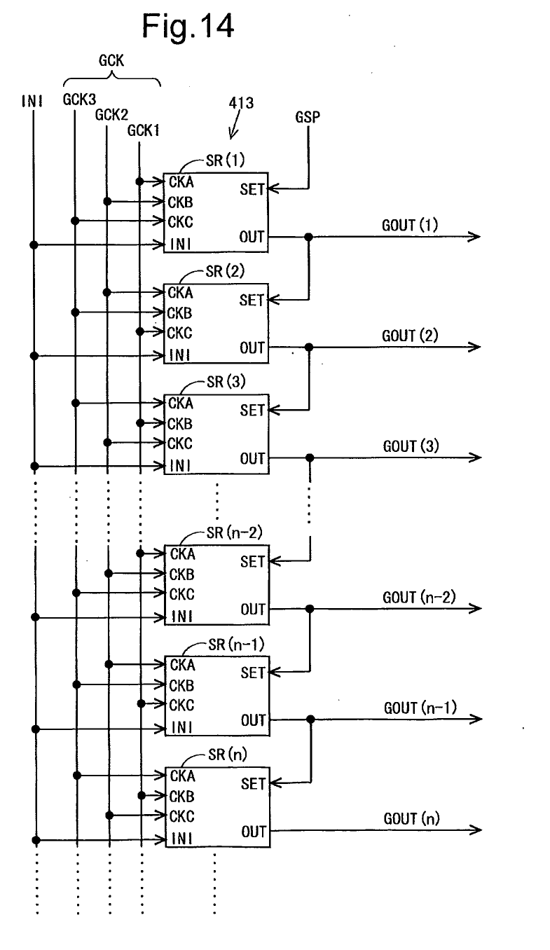

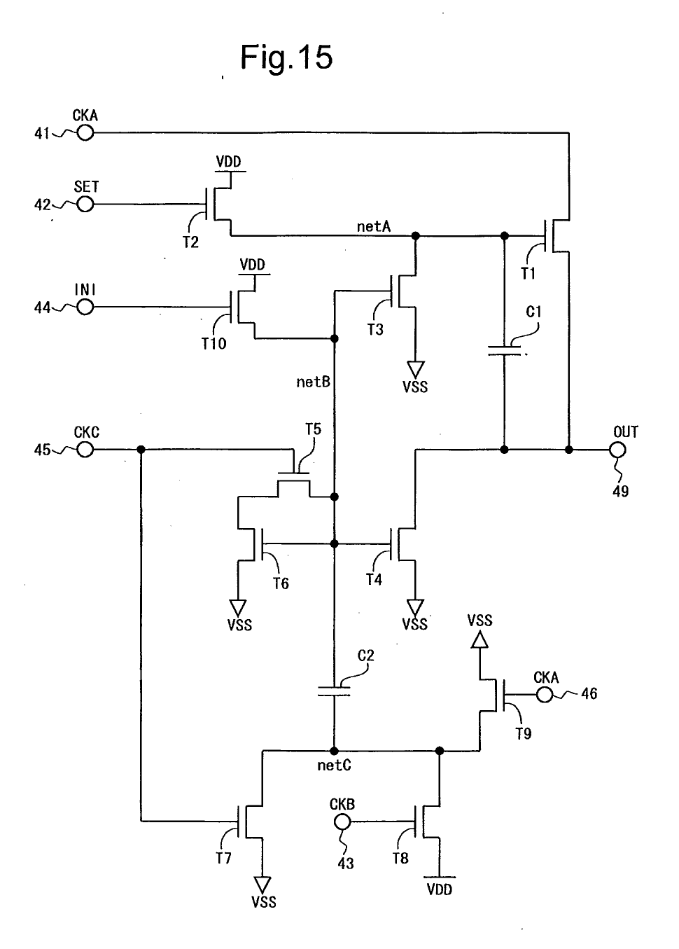

In the present embodiment, an overall configuration and a schematic configuration of a gate driver are substantially the same as those in the above-described first embodiment which are shown in FIGS. 2 and 3, and thus, a detailed description thereof is omitted. FIG. 14 is a block diagram showing a configuration of a shift register 413 in a gate driver 40 in the present embodiment. FIG. 15 is a circuit diagram showing a configuration of a bistable circuit in the present embodiment. The configuration in the present embodiment is a combined version of the configuration in the above-described second embodiment (see FIGS. 8 and 9) and the configuration in the above-described third embodiment (see FIGS. 11 and 12).

<4.2 Operation of the Shift Register>

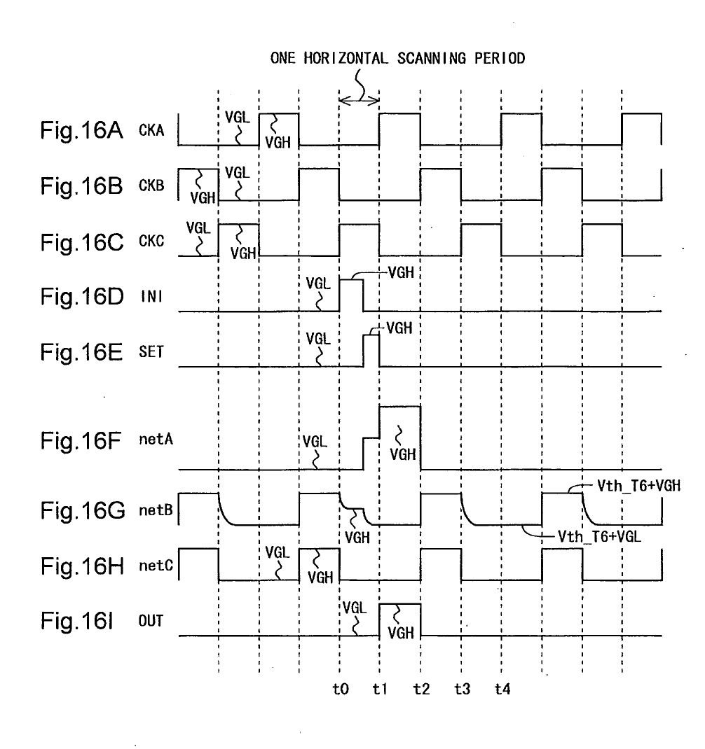

Next, with reference to FIGS. 15 and 16A to 16I, the operation of the shift register 413 in the present embodiment will be described. As with the second embodiment, when reaching time point to, a pulse of an initialization signal INI is provided to input terminals 44 of all bistable circuits SR(1) to SR(n) composing the shift register 413. By this, in all of the bistable circuits SR(1) to SR(n), the potentials of netBs are brought to VGH, and the potentials of netAs and the potentials of state signals OUT are brought to VGL. Thereafter, by providing a pulse of a set signal SET to an input terminal 42 of the bistable circuit SR(1) of the first stage, the same operation as that at time point t0 in the first embodiment is performed.

During the period from t1 to t3, the same operation as that in the third embodiment is performed. When reaching time point t3, the potential of a second clock CKB changes from VGH to VGL and the potential of a third clock CKC changes from VGL to VGH. By this, as with the third embodiment, the potential of a netC is brought to VGL and the potential of the netB decreases to “Vth_T6+VGL”.

<4.3 Effects>

According to the present embodiment, the same effect as that obtained in the first embodiment is obtained; in addition, as with the second embodiment, the operation of the shift register is stabilized and as with the third embodiment, a shift in threshold voltage in a positive direction for thin film transistors T3, T4, and T6 is suppressed.

### 5. Variants, etc.

Although, in the above-described embodiments, description is made using a liquid crystal display device as an example, the present invention is not limited thereto. As long as the configuration is made such that a shift register is provided, the present invention can also be applied to display devices other than liquid crystal display devices, such as display devices having arranged therein self-light emitting type light-emitting devices such as organic EL (ElectroLuminescence) devices or Light-Emitting Diodes (LEDs).

In addition, although, in the above-described embodiments, description is made using an example in which TFTs (Thin Film Transistors) which are MOS transistors (here, MOS transistors with a silicon gate MOS structure included are referred to as MOS transistors) formed on an insulating substrate such as a glass substrate are used as transistors, the present invention is not limited thereto. The present invention can be applied to any drive element as long as the drive element is of a voltage control type in which an output current is controlled by a control voltage applied to a current control terminal, and the control voltage of the element has a threshold voltage that determines whether there is an output current.

Furthermore, although in the above-described embodiments thin film transistors T3, T4, and T6 are designed to have the same transistor characteristics, they may be designed such that one of the thin film transistors T3 and T4 having a larger threshold shift and the thin film transistor T6 have the same transistor characteristics.

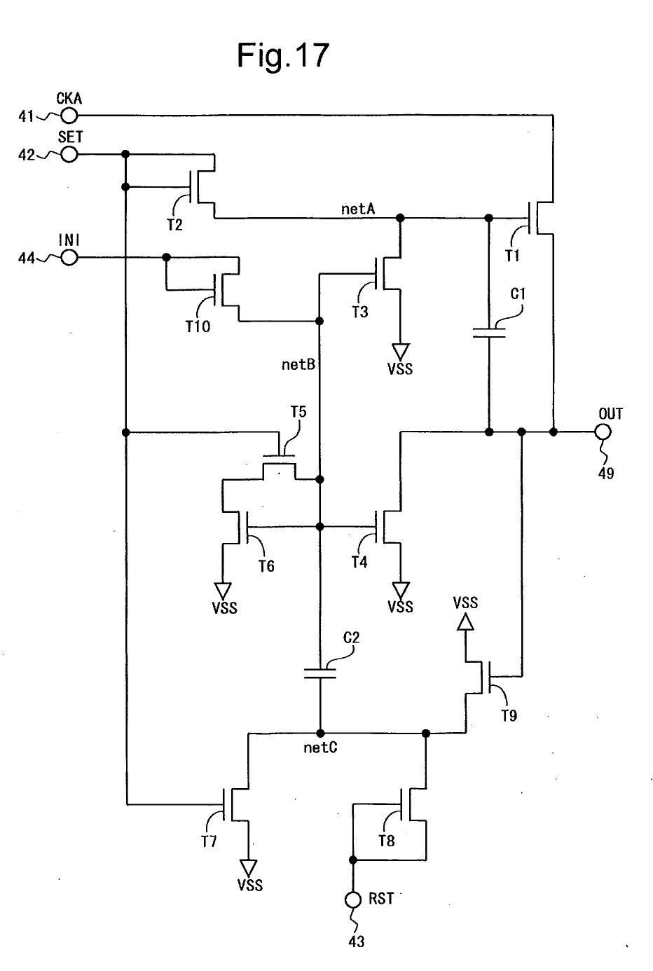

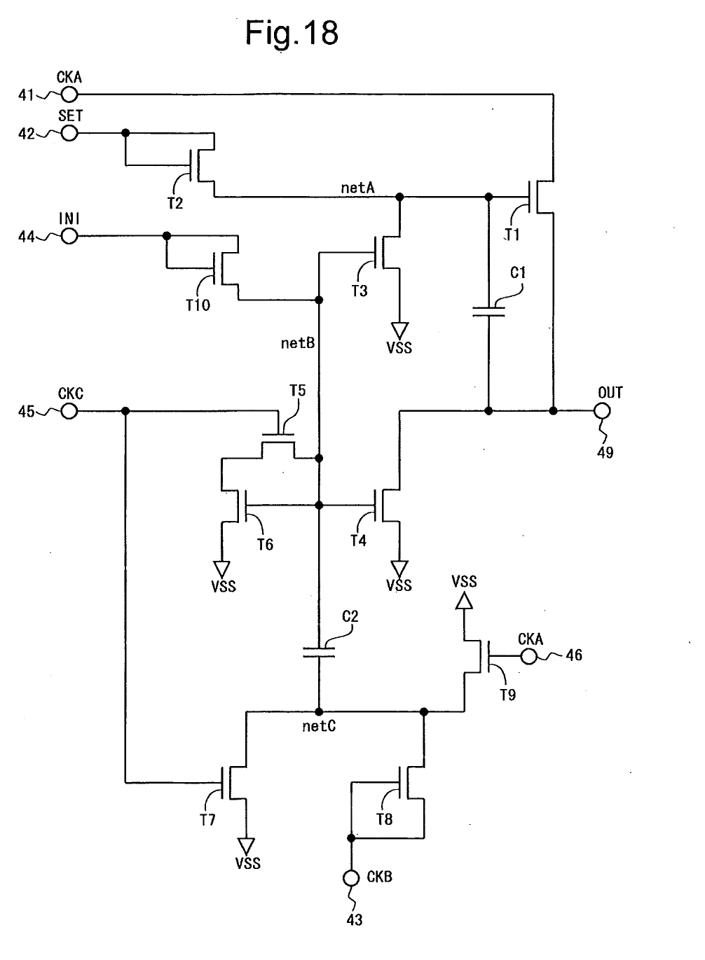

Furthermore, as for the configurations of thin film transistors T2, T8, and T10 in the second and fourth embodiments, the configuration maybe such that the gate and drain terminals of each of those thin film transistors are short-circuited (i.e., a diode-connected configuration). Namely, the configuration of bistable circuits composing a shift register maybe the one shown in FIG. 17 or may be the one shown in FIG. 18. In the case of such configurations, when the gate potential of a thin film transistor is brought to VGH, the thin film transistor is placed in an on state and thus the source potential thereof is brought to VDD.

The present invention is not limited to the above-described embodiments and various changes may be made within the scope defined by the claims. An embodiment obtained by appropriately combining technical means disclosed in different embodiments is also encompassed in the technical scope of the present invention.

### DESCRIPTION OF REFERENCE CHARACTERS

10: DISPLAY UNIT

15: DISPLAY SIGNAL GENERATING CIRCUIT

20: SYSTEM CONTROLLER

30: SOURCE DRIVER (VIDEO SIGNAL LINE DRIVE CIRCUIT)

40: GATE DRIVER (SCANNING SIGNAL LINE DRIVE CIRCUIT)

41 to 46: INPUT TERMINAL (OF BISTABLE CIRCUIT)

49: OUTPUT TERMINAL (OF BISTABLE CIRCUIT)

410 to 413: SHIFT REGISTER

SR(1) to SR(n): BISTABLE CIRCUIT

T1 to T9: THIN FILM TRANSISTOR

C1 and C2: CAPACITOR

GL1 to GLn: GATE BUS LINE

SL1 to SLm: SOURCE BUS LINE

GSP: GATE START PULSE SIGNAL

GEP: GATE END PULSE SIGNAL

CKA: FIRST CLOCK

CKB: SECOND CLOCK

CKC: THIRD CLOCK

GOUT(1) to GOUT(n): SCANNING SIGNAL

OUT: STATE SIGNAL

SET: SET SIGNAL

RST: RESET SIGNAL

Vth_T6: THRESHOLD VOLTAGE OF THIN FILM TRANSISTOR T6

1. A shift register comprising a plurality of bistable circuits having a first state and a second state and connected to each other in series, the plurality of bistable circuits being sequentially placed in the first state based on a clock signal, the clock signal being provided from an external source of each bistable circuit and periodically repeating a high-level potential and a low-level potential, wherein
each bistable circuit includes:
an output node that outputs a state signal indicating either one of the first state and the second state;
a first transistor having a second electrode to which the clock signal is provided, and having a third electrode connected to the output node;
a first node charging portion for charging a first node based on the state signal outputted from a bistable circuit of a previous stage of the bistable circuit, the first node being connected to a first electrode of the first transistor;
a third transistor having a second electrode connected to the first node and having a third electrode to which a low-level potential is provided;
a fourth transistor having a second electrode connected to the output node and having a third electrode to which a low-level potential is provided; and
a second node potential control portion for setting a potential of a second node to a relatively low-level potential and a relatively high-level potential, the second node being connected to a first electrode of the third transistor and a first electrode of the fourth transistor, and
the second node potential control portion includes:
a fifth transistor having a first electrode to which a previous stage state signal that is the state signal outputted from a bistable circuit of a previous stage of each bistable circuit is provided, or a signal that goes to a high level at least during a period during which the previous stage state signal is placed in the first state is provided, and having a second electrode connected to the second node; and
a sixth transistor having a first electrode connected to the second node, having a second electrode to which a third electrode of the fifth transistor is connected, and having a third electrode to which a potential with a magnitude is provided, the magnitude being equal to the low-level potentials provided to the third electrode of the third transistor and the third electrode of the fourth transistor.

2. The shift register according to claim 1, wherein the third transistor, the fourth transistor, and the sixth transistor have an equal ratio of a channel width to a channel length.

3. The shift register according to claim 2, wherein the sixth transistor is disposed to be adjacent to at least one of the third transistor and the fourth transistor.

4. The shift register according to claim 1, wherein
the second node potential control portion includes:
a second node potential low-level setting portion including the fifth transistor and the sixth transistor and setting the potential of the second node to the relatively low-level potential during a period during which the third transistor and the fourth transistor are to be placed in an off state; and
a second node potential high-level setting portion that sets the potential of the second node to the relatively high-level potential by increasing the potential of the second node by a predetermined amount of voltage upon changing from a period during which the third transistor and the fourth transistor are to be placed in an off state to a period during which the third transistor and the fourth transistor are to be placed in an on state.

5. The shift register according to claim 4, wherein
the second node potential high-level setting portion includes:
a seventh transistor having a first electrode to which a previous stage state signal that is the state signal outputted from a bistable circuit of a previous stage of each bistable circuit is provided, or a signal that goes to a high level at least during a period during which the previous stage state signal is placed in the first state is provided, and having a third electrode to which a low-level potential is provided;
a third node charging portion for charging a third node connected to a second electrode of the seventh transistor, based on a subsequent stage state signal that is the state signal outputted from a bistable circuit of a subsequent stage of each bistable circuit, or based on a signal that goes to a high level at least during a period during which the subsequent stage state signal is placed in the first state; and
a capacitor having one end connected to the second node and having an other end connected to the third node.

6. The shift register according to claim 5, wherein the third node charging portion comprises an eighth transistor having a first electrode to which a signal that goes to a high level at least during a period during which the subsequent stage state signal is placed in the first state is provided, having a second electrode to which a high-level potential is provided, and having a third electrode connected to the third node.

7. The shift register according to claim 5, wherein the second node potential high-level setting portion further includes a ninth transistor having a first electrode which is connected to the output node or to which a signal that goes to a high level at least during a period during which the state signal outputted from each bistable circuit is placed in the first state is provided, having a second electrode connected to the third node, and having a third electrode to which a low-level potential is provided.

8. The shift register according to claim 4, wherein
the second node potential high-level setting portion includes:
a seventh transistor having a first electrode to which a clock signal that goes to a high level at least during the period during which the previous stage state signal is placed in the first state is provided, and having a third electrode to which a low-level potential is provided;
an eighth transistor having a first electrode to which a clock signal that goes to a high level at least during a period during which a subsequent stage state signal is placed in the first state is provided, having a second electrode to which a high-level potential is provided, and having a third electrode connected to a third node connected to a second electrode of the seventh transistor, the subsequent stage state signal being the state signal outputted from a bistable circuit of a subsequent stage of each bistable circuit;
a ninth transistor having a first electrode to which a clock signal that goes to a high level at least during a period during which the state signal outputted from each bistable circuit is placed in the first state is provided, having a second electrode connected to the third node, and having a third electrode to which a low-level potential is provided; and
a capacitor having one end connected to the second node and having an other end connected to the third node,
three-phase clock signals with different phases are provided to the first electrode of the seventh transistor, the first electrode of the eighth transistor, and the first electrode of the ninth transistor, respectively, and
a same clock signal is provided to the first electrode of the seventh transistor and the first electrode of the fifth transistor.

9. The shift register according to claim 1, wherein each bistable circuit further includes a second node initialization portion that sets the potential of the second node to a predetermined potential based on an initialization pulse provided to the plurality of bistable circuits at common timing.

10. The shift register according to claim 9, wherein the second node initialization portion includes a tenth transistor having a first electrode to which the initialization pulse is provided, having a second electrode to which a high-level potential is provided, and having a third electrode connected to the second node.

11. The shift register according to claim 1, wherein each transistor is formed using amorphous silicon or microcrystalline silicon for a semiconductor layer.

12. A scanning signal line drive circuit of a display device that drives a plurality of scanning signal lines arranged in a display unit, the scanning signal line drive circuit comprising:
a shift register according to claim 1, wherein
the plurality of bistable circuits are provided so as to have a one-to-one correspondence with the plurality of scanning signal lines, and
each bistable circuit provides the state signal outputted from the output node, to a corresponding scanning signal line of the bistable circuit as a scanning signal.

13. A display device including the display unit and comprising a scanning signal line drive circuit according to claim 12.

14. A method of driving a shift register including a plurality of bistable circuits having a first state and a second state and connected to each other in series, the plurality of bistable circuits being sequentially placed in the first state based on a clock signal, the clock signal being provided from an external source of each bistable circuit and periodically repeating a high-level potential and a low-level potential, the method comprising:
a first driving step of changing each bistable circuit from the second state to the first state based on a first instruction signal provided from an external source of the bistable circuit; and
a second driving step of changing each bistable circuit from the first state to the second state based on a second instruction signal provided from an external source of the bistable circuit, wherein
each bistable circuit includes:
an output node that outputs a state signal indicating either one of the first state and the second state;
a first transistor having a second electrode to which the clock signal is provided, and having a third electrode connected to the output node;
a first node charging portion for charging a first node based on the state signal outputted from a bistable circuit of a previous stage of the bistable circuit and provided as the first instruction signal, the first node being connected to a first electrode of the first transistor;
a third transistor having a second electrode connected to the first node and having a third electrode to which a low-level potential is provided;
a fourth transistor having a second electrode connected to the output node and having a third electrode to which a low-level potential is provided; and
a second node potential control portion for setting a potential of a second node to a relatively low-level potential and a relatively high-level potential, the second node being connected to a first electrode of the third transistor and a first electrode of the fourth transistor,
the second node potential control portion includes:
a fifth transistor having a first electrode to which a previous stage state signal that is the state signal outputted from the bistable circuit of the previous stage of the bistable circuit is provided, or a signal that goes to a high level at least during a period during which the previous stage state signal is placed in the first state is provided, and having a second electrode connected to the second node; and
a sixth transistor having a first electrode connected to the second node, having a second electrode to which a third electrode of the fifth transistor is connected, and having a third electrode to which a potential with a magnitude is provided, the magnitude being equal to the low-level potentials provided to the third electrode of the third transistor and the third electrode of the fourth transistor,
in the first driving step, the potential of the second node is set to the relatively low-level potential by the second node potential control portion, and
in the second driving step, the potential of the second node is set to the relatively high-level potential by the second node potential control portion.

15. The drive method according to claim 14, wherein
the second node potential control portion includes:
a second node potential low-level setting portion including the fifth transistor and the sixth transistor, for setting the potential of the second node to the relatively low-level potential; and
a second node potential high-level setting portion for setting the potential of the second node to the relatively high-level potential,
the first driving step includes:
a first node charging step of charging the first node; and
an output node charging step of changing the state indicated by the state signal from the second state to the first state by changing a potential of the clock signal provided to the second electrode of the first transistor from a low level to a high level when the first node is being charged,
in the first node charging step, the potential of the second node is set to the relatively low-level potential by the second node potential low-level setting portion, and
in the second driving step, the potential of the second node is set to the relatively high-level potential by increasing the potential of the second node by a predetermined amount of voltage by the second node potential high-level setting portion.

16. The drive method according to claim 15, wherein
the second node potential high-level setting portion includes:
a seventh transistor having a first electrode to which a clock signal that goes to a high level at least during a period during which the previous stage state signal is placed in the first state is provided, and having a third electrode to which a low-level potential is provided;
an eighth transistor having a first electrode to which a clock signal that goes to a high level at least during a period during which a subsequent stage state signal is placed in the first state is provided, having a second electrode to which a high-level potential is provided, and having a third electrode connected to a third node connected to a second electrode of the seventh transistor, the subsequent stage state signal being the state signal outputted from a bistable circuit of a subsequent stage of each bistable circuit;
a ninth transistor having a first electrode to which a clock signal that goes to a high level at least during a period during which the state signal outputted from each bistable circuit is placed in the first state is provided, having a second electrode connected to the third node, and having a third electrode to which a low-level potential is provided; and
a capacitor having one end connected to the second node and having an other end connected to the third node,
three-phase clock signals with different phases are provided to the first electrode of the seventh transistor, the first electrode of the eighth transistor, and the first electrode of the ninth transistor, respectively, and
a same clock signal is provided to the first electrode of the seventh transistor and the first electrode of the fifth transistor.

17. The drive method according to claim 14, further comprising a second node initializing step of setting the potentials of the second nodes in the plurality of bistable circuits to a predetermined potential based on an initialization pulse provided to the plurality of bistable circuits at common timing.
